(19) United States
(12) Patent Application Publication
(10) Pub. No.: US 2018/0098437 A1
(43) Pub. Date: Apr. 5, 2018

(54) WIRING SYSTEM

(71) Applicant: The Charles Stark Draper Laboratory, Inc., Cambridge, MA (US)

(72) Inventors: Caprice Gray Haley, Cambridge, MA (US); Amy DuweI, Cambridge, MA (US); Anthony Kopa, Cambridge, MA (US); Seth Davis, Cambridge, MA (US); Andrew P. Magyar, Cambridge, MA (US); Brian Smith, Cambridge, MA (US); Mitchell W. Meinhold, Cambridge, MA (US); Sara Barron, Cambridge, MA (US); Gregory Romano, Cambridge, MA (US); Richard Morrison, Cambridge, MA (US); Hongmei Zhang, Cambridge, MA (US)

(21) Appl. No.: 15/592,694

(22) Filed: May 11, 2017

Related U.S. Application Data
(60) Provisional application No. 62/404,135, filed on Oct. 4, 2016.
(60) Provisional application No. 62/462,625, filed on Feb. 23, 2017.
(60) Provisional application No. 62/464,164, filed on Feb. 27, 2017.

(51) Int. Cl. H05K 3/34; H01B 13/016; H05K 1/11; H05K 3/32; H01R 43/02; H01R 9/05

(52) U.S. Cl. CPC H05K 3/34; H01B 13/016; H01R 9/0515; H05K 3/328; H01R 43/02; H05K 1/115

(57) ABSTRACT

A method for attaching a prefabricated miniature coaxial wire to a first electrical connection point, the prefabricated miniature coaxial wire having an electrically conductive core disposed within an electrical insulation layer disposed within an electrically conductive shield layer, includes attaching an exposed portion of the electrically conductive core at a distal end of the prefabricated miniature coaxial wire to the first electrical connection point, thereby establishing electrical conductivity between the electrically conductive core and the first electrical connection point, depositing a layer of electrically insulating material onto the exposed portion of the electrically conductive core such that the exposed portion of the electrically conductive core and the first electrical connection point is encased in the layer of electrically insulating material, and connecting the electrically conductive shield layer to a second electrical connection point using a connector formed from an electrically conductive material.

### CROSS-REFERENCE TO RELATED APPLICATIONS

This application claims the benefit of U.S. Provisional Application No. 62/404,135 filed Oct. 4, 2016, U.S. Provisional Application No. 62/462,625 filed Feb. 23, 2017, and U.S. Provisional Application No. 62/464,164 filed Feb. 27, 2017, the contents of which are incorporated by reference.

### BACKGROUND

This invention relates to wiring systems.

With today's high density interconnection technology, skilled engineers require weeks or months to design and layout a multi-layer printed circuit board. For high-volume manufacturing this non-recurring engineering (NRE) cost is amortized over thousands or more units. For prototypes and low-volume manufacturing, this NRE is a major cost contributor that cannot be amortized.

### SUMMARY

In a general aspect, a method for attaching a prefabricated miniature coaxial wire to a first electrical connection point, the prefabricated miniature coaxial wire having an electrically conductive core disposed within an electrical insulation layer disposed within an electrically conductive shield layer, includes attaching an exposed portion of the electrically conductive core at a distal end of the prefabricated miniature coaxial wire to the first electrical connection point, thereby establishing electrical conductivity between the electrically conductive core and the first electrical connection point, depositing a layer of electrically insulating material onto the exposed portion of the electrically conductive core such that the exposed portion of the electrically conductive core and the first electrical connection point is encased in the layer of electrically insulating material, and connecting the electrically conductive shield layer to a second electrical connection point using a connector formed from an electrically conductive material.

Aspects may include one or more of the following features.

Connecting the electrically conductive shield layer to the second electrical connection point using the connector may include forming the connector including depositing a layer of the electrically conductive material onto at least a portion of the electrically conductive shield layer and onto the second electrical connection point, the connector establishing electrical conductivity between the electrically conductive shield layer and the second electrical connection point. Depositing the layer of the electrically conductive material onto the at least a portion of the electrically conductive shield layer and onto the second electrical connection point may include one of flowing the electrically conductive material onto the at least a portion of the electrically conductive shield layer and onto the second electrical connection point, spray coating the electrically conductive material onto the at least a portion of the electrically conductive shield layer and onto the second electrical connection point, vapor depositing the electrically conductive material onto the at least a portion of the electrically conductive shield layer and onto the second electrical connection point, sputtering the electrically conductive material onto the at least a portion of the electrically conductive shield layer and onto the second electrical connection point, and plating the electrically conductive material onto the at least a portion of the electrically conductive shield layer and onto the second electrical connection point.

The layer of electrically insulating material may encase the first electrical connection point and the layer of electrically conductive material encases the layer of electrically insulating material. The layer of electrically conductive material may partially encase the layer of electrically insulating material. An exposed portion of the electrical insulation layer at the distal end of the prefabricated miniature coaxial wire may be encased in the layer of electrically of insulating material. Depositing the layer of electrically insulating material onto the exposed portion of the electrically conductive core may include depositing a bead of the electrically insulating material onto the exposed portion of the electrically conductive core.

Depositing the layer of electrically insulating material onto the exposed portion of the electrically conductive core may include flowing the electrically insulating material onto the exposed portion of the electrically conductive core. Depositing the layer of electrically insulating material onto the exposed portion of the electrically conductive core may include vapor depositing the electrically insulating material onto the exposed portion of the electrically conductive core. Vapor depositing the electrically insulating material may include selectively vapor deposition of polymeric material. Depositing the layer of electrically insulating material onto the exposed portion of the electrically conductive core may include aerosol jetting the electrically insulating material onto the exposed portion of the electrically conductive core. Connecting the electrically conductive shield layer to the second electrical connection point using the connector may include printing the connector as a strip of the electrically conductive material.

The connector may include a wire and connecting the electrically conductive shield layer to the second electrical connection point using the connector may include attaching a first end of the wire to the first electrical connection point and attaching a second end of the wire to the second electrical connection point. Attaching the exposed portion of the electrically conductive core to the first electrical connection point may include attaching a conductive pad to the first electrical connection point and then attaching the electrically conductive core to the conductive pad. The first electrical connection point may be a connector pad on a bare die. The electrical first connection point may be a connector pad on a packaged part. The first electrical connection point may be a ball on a ball grid array.

The first electrical connection point may include a discrete adapter bridging two electrical connection points. The first electrical connection point may be disposed on a passive electrical component. The first electrical connection point may include an electrically conductive via disposed in a circuit board. The first electrical connection point may include a conductive plane or a conductive trace disposed on a circuit board. Attaching the exposed portion of the electrically conductive core to the first electrical connection point may include soldering the electrically conductive core to the first electrical connection point. Attaching the exposed portion of the electrically conductive core to the first electrical connection point may include welding the electrically conductive core to the first electrical connection point. Welding may include one or more of electron beam welding, ultrasonic welding, cold welding, laser welding, or resistance welding.

Attaching the exposed portion of the electrically conductive core to the first electrical connection point may include one or more of diffusion bonding the electrically conductive core to the first electrical connection point, brazing the electrically conductive core to the first electrical connection point, sintering bonding the electrically conductive core to the first electrical connection point, or attaching the exposed portion to the first electrical connection point using a conductive adhesive. The second electrical connection point may include a ground connection point. The method may include forming the connector including welding the electrically conductive shield layer to a second electrical connection point. The method may include forming the connector including thermo-compression bonding the electrically conductive shield layer to a second electrical connection point. The method may include forming the connector including ultrasonically bonding the electrically conductive shield layer to a second electrical connection point.

In another general aspect, an automated tool is configured to performing any one of the above steps.

In another general aspect, a method of fabricating a miniature coaxial wire from an insulated wire, the insulated wire including an electrically conductive core surrounded by an electrically insulating layer, the insulated wire having a first segment and a second segment separated by a third segment includes depositing an adhesion layer on the electrically insulating layer of the insulated wire including depositing a first portion of the adhesion layer on the first segment of the insulated wire, depositing a second portion of the adhesion layer on the second segment of the insulated wire, depositing an electrically conductive shield layer on the adhesion layer including depositing a first portion of the electrically conductive shield layer on the first portion of the adhesion layer and depositing a second portion of the electrically conductive shield layer on the second portion of the adhesion layer, and removing the electrically insulating layer from the third segment of the insulated wire while maintaining continuity of the electrically conductive core of the first segment, the second segment, and the third segment of the insulated wire.

Aspects may include one or more of the following features.

The method may include covering the third segment of the insulated wire prior to depositing the electrically conductive shield layer on the adhesion layer and uncovering the third segment of the insulated wire after depositing the electrically conductive shield layer on the adhesion layer and before removing the electrically insulating layer from the third segment of the insulated wire. Covering the third segment of the insulated wire may include arranging the insulated wire in a fixture, the fixture configured to cover the third segment of the insulated wire while leaving the first portion of the adhesion layer and the second portion of the adhesion layer exposed, and uncovering the third segment of the insulated wire includes removing the insulated wire from the fixture.

Depositing the adhesion layer on the electrically insulating layer of the insulated wire may include depositing a third portion of the adhesion layer on the third segment of the insulated wire, covering the third segment of the insulated wire includes covering the third portion of the adhesion layer, and uncovering the third segment of the insulated wire includes uncovering the third portion of the adhesion layer. The method may include removing the third portion of the adhesion layer while maintaining continuity of the electrically conductive core of the first segment, the second segment, and the third segment of the insulated wire.

Covering the third portion of the adhesion layer may include depositing a masking bead on the third portion of the adhesion layer prior to depositing the electrically conductive shield layer on the adhesion layer, and uncovering the third portion of the adhesion layer may include removing the masking bead from the third portion of the adhesion layer after depositing the electrically conductive shield layer and prior to removing the third portion of the adhesion layer and the electrically insulating layer from the third segment of the insulated wire. Removing the third portion of the adhesion layer and the electrically insulating layer from the third segment of the insulated wire may include removing the third portion of the adhesion layer using a chemical etching procedure and removing the electrically insulating layer from the third segment of the insulated wire may include laser cutting the electrically insulating layer of the third segment of the insulated wire.

Depositing the adhesion layer on the electrically insulating layer of the insulated wire may include depositing a third portion of the adhesion layer on the third segment of the insulated wire and depositing the electrically conductive shield layer on the adhesion layer may include depositing a third portion of the electrically conductive shield layer on the third portion of the adhesion layer. The method may include removing the third portion of the electrically conductive shield layer while maintaining continuity of the electrically conductive core of the first segment, the second segment, and the third segment of the insulated wire, the removal occurring after removal of the third portion of the electrically conductive shield layer and removing the third portion of the adhesion layer while maintaining continuity of the electrically conductive core of the first segment, the second segment, and the third segment of the insulated wire, the removal occurring after removal of the third portion of the electrically conductive shield layer.

The electrically conductive shield layer may be formed from a conductive, thermally removable material and removing the third portion of the electrically conductive shield layer may include applying thermal energy to the third portion of the electrically conductive shield layer. The conductive, thermally removable material may include a solder material. Depositing the electrically conductive shield layer on the adhesion layer may include performing an electroplating procedure. The conductive shield material may be formed from one or more of a copper material, a gold material, a silver material, a tin material, a nickel material, or an alloy of one or more of a copper material, a gold material, a silver material, a tin material, and a nickel material.

Depositing the electrically conductive shield layer on the adhesion layer may include performing an electroless plating procedure. The conductive shield material may be formed from one or more of a copper material, a gold material, a silver material, a tin material, a nickel material, or an alloy of one or more of a copper material, a gold material, a silver material, a tin material, a nickel material. Depositing the electrically conductive shield layer on the adhesion layer may include drawing the insulated wire through a suspension of metallic particles in a polymeric material. The metallic particles may include one or more of metallic flakes, metallic nanoparticles, and metallic microparticles. The metallic particles may be formed from one or more of a copper material, a gold material, a silver material, a tin material, a nickel material, or an alloy of one or more of a copper material, a gold material, a silver material, a tin material, a nickel material.

The method may include feeding the insulated wire from a spooling fixture. The method may include cutting through the conductive core of the third segment of the insulated wire after removing the third portion of the adhesion layer and the electrically insulating layer from the third segment of the insulated wire. The method may include cutting through the conductive core of the third segment of the insulated wire after removing the third portion of the adhesion layer and before removing the electrically insulating layer from the third segment of the insulated wire. The method may include forming the insulated wire including depositing the insulating layer onto the electrically conductive core using a vapor deposition process. Removing the electrically insulating layer from the third segment of the insulated wire may include laser cutting the electrically insulating layer of the third segment of the insulated wire. The adhesion layer may be formed from an electrically conductive metallic material. The adhesion layer may be formed from an organic adhesion promoter.

In another general aspect, a method of fabricating a miniature coaxial wire, includes depositing a masking layer on a substrate according to a masking pattern resulting in a first portion of the substrate being covered by the masking layer and a second portion of the substrate being uncovered by the masking layer, removing material from the second portion of the substrate to form a first cavity in the second portion of the substrate, removing the masking layer from the substrate after removal of the material from the second portion of the substrate, forming the miniature coaxial wire in the first cavity in the second portion of the substrate after removing the masking layer. The forming includes depositing a first conductive shield layer in the first cavity such that the first cavity is lined with the first conductive shield layer, the first conductive shield layer forming a second cavity within the first cavity, depositing a first electrically insulating layer in the second cavity such that the second cavity is lined with the first electrically insulating layer, first electrically the insulating layer forming a third cavity within the second cavity, depositing an electrically conductive core in the third cavity, depositing a second electrically insulating layer on the electrically conductive core, wherein the first electrically insulating layer and the second electrically insulating layer encase the conductive core, depositing a second electrically conductive shield layer on the second electrically insulating layer, wherein the first electrically conductive shield layer and the second electrically conductive shield layer encase the first electrically insulating layer and the second electrically insulating layer, and detaching the miniature coaxial wire from the substrate including detaching the first electrically conductive shield layer from the first cavity in the substrate.

Aspects may include one or more of the following features.

Depositing the masking layer may include depositing a polysilicon layer on the substrate. The substrate may include a fused silica wafer. Removing material from the second portion of the substrate may include chemically etching the second portion of the substrate. Chemically etching the second portion of the substrate may include hydrofluoric acid etching of the second portion of the substrate. Depositing the first electrically conductive shield layer in the first cavity may include depositing a seed layer in the first cavity and then depositing the first electrically conductive shield layer. The first electrically conductive shield layer may be formed from a copper material. Depositing the first electrically conductive shield layer may include one of electroplating or electroless plating the first electrically conductive shield layer. Depositing the first electrically insulating layer may include depositing a first polyimide layer and depositing the second electrically insulating layer includes depositing a second polyimide layer.

Depositing the first polyimide layer and the second polyimide layer may include spraying the polyimide layers. Depositing the electrically conductive core in the third cavity may include depositing a seed layer in the third cavity and then depositing the electrically conductive core. Depositing the electrically conductive core in the third cavity may include one of electroplating or electroless plating the electrically conductive core. Depositing the second electrically conductive shield layer on the second electrically insulating layer may include depositing a seed layer on the second electrically insulating layer and then depositing the second electrically conductive shield layer. The second electrically conductive shield layer may be formed from a copper material. Detaching the miniature coaxial wire from the substrate may include performing a glass etching process.

In another general aspect, an apparatus for removing one or more layers from a wire, the wire including an inner core extending along a first axis and a first layer extending along the first axis and surrounding the inner core, includes a feeding mechanism configured to move the wire in a direction along the first axis and to rotate the wire about the first axis and a first rotating blade configured cut into the wire to a first predetermined depth as the wire rotates about the first axis. The feeding mechanism is configured to move the wire along the first axis into a cutting position where the first rotating blade engages the wire and cuts into the wire to the first predetermined depth as the wire rotates about the first axis.

Aspects may include one or more of the following features.

The feeding mechanism may include a first feeding rod extending along a second axis, substantially transverse to the first axis and a second feeding rod extending along a third axis spaced from the second axis and extending substantially transverse to the first axis. The first feeding rod may be configured to rotate about the second axis in a counter clockwise direction and the second feeding rod may be configured to rotate about the third axis in a clockwise direction to move the wire in the direction along the first axis. The first feeding rod may be configured to move in a first direction along the second axis and the second feeding rod may be configured to move in a second direction, opposite the first direction, along the third axis to rotate the wire about the first axis.

The first predetermined depth may be substantially equal to a thickness of the first layer. The first rotating blade may extend from a cylindrical drum with a length equal to the first predetermined depth, the cylindrical drum providing a depth stop. The first rotating blade, the second rotating blade, and the third rotating blade may be formed as wires adhered to the cylindrical drum. The wire may include a second layer extending along the first axis and surrounding the first layer and the inner core, the apparatus further comprising a second rotating blade configured cut into the wire to a second predetermined depth as the wire rotates about the first axis. The first predetermined depth may be substantially equal to a thickness of the first layer and the second predetermined depth may be substantially equal to the sum of the thickness of the first layer and the thickness of the second layer.

The first rotating blade may extend from a cylindrical drum with a length equal to the first predetermined depth, the second rotating blade may extend from the cylindrical drum with a length equal to the second predetermined depth, the cylindrical drum providing a depth stop. The first rotating blade and the second rotating blade may be formed as wires adhered to the cylindrical drum. The wire may include a third layer extending along the first axis and surrounding the second layer, the first layer, and the inner core, the apparatus may be further comprising a third rotating blade configured cut into the wire to a third predetermined depth as the wire rotates about the first axis. The first predetermined depth may be substantially equal to a thickness of the first layer, the second predetermined depth may be substantially equal to the sum of the thickness of the first layer and the thickness of the second layer, and the third predetermined depth may be substantially equal to the sum of the thickness of the first layer, the thickness of the second layer, and the thickness of the third layer.

The first rotating blade may extend from a cylindrical drum with a length equal to the first predetermined depth, the second rotating blade may extend from the cylindrical drum with a length equal to the second predetermined depth, and the third rotating blade may extend from the cylindrical drum with a length equal to the third predetermined depth, the cylindrical drum providing a depth stop. The first rotating blade, the second rotating blade, and the third rotating blade may be formed as wires adhered to the cylindrical drum. The feeding mechanism may be configured to rotate the wire at least 360 degrees about the first axis.

Embodiments described herein feature methods and apparatus for replacing conventional planar electrical interconnects (e.g. printed circuit board or silicon interposer) with miniature coaxial cables (coax). A coaxial cable has an inner conductor wire (core) surrounded by an outer conductor (shield), with an insulator separating the two. In typical operation, the core and shield carry equal and opposite currents and they complete a circuit by connecting to other electrical components at both ends of the cable. There are fundamental advantages to designing with coax instead of conventional interconnects, but this is not done for inter-chip interconnects today because coax is generally too large and cannot be attached to chips.

One aspect of the present invention is the small size, connections, and impedance of the coaxial cables which in turn drives their materials, fabrication methods and dimensions. Embodiments use a range of coax sizes for interconnects which cover a range of size applications, e.g. pads on 30 um pitch on a bare die, solder balls on 400 um pitch, millimeter-scale surface mount components, and more. The impedance of coax is set by the relative dimensions of the two conductors and the insulator. Typical coax has impedance of 50 Ohms or 75 Ohms while all other values are extremely rare. Embodiments address typical 50 Ohm coax, but may also feature coax with impedance less than 1 Ohm specifically for DC power distribution, which is an unusual application for coax.

In embodiments, the present invention features assembly and attachment by automated methods such as pick-and-place, wire bonding and additive manufacturing methods. In the pick-and-place method, cables may be prefabricated, cut to length, and then attached by thermosonic bonding or soldering to electronic components. Once an electrical schematic has been generated based on customer needs, an exemplary assembly method may comprise 3 steps: (1) bond the wire core, (2) insulate the core/signal connection from the wire shield, (3) connect the shield to ground by adding an additional conductor bridge. All wire handling and attachment processes can be done with a limited number of automated tools.

Among other advantages, a system of miniature coaxial cables for electrical interconnection according to the present invention will enable the rapid design and fabrication of customized, miniature electronic systems. With today's technology, skilled engineers require weeks or months to design and layout a multi-layer printed circuit board. For high-volume manufacturing this non-recurring engineering (NRE) cost is amortized over thousands or more units. For prototypes and low-volume manufacturing, this NRE is a major cost contributor that cannot be amortized. Fabrication also takes several weeks, which means that alterations or design changes are costly and slow. The present invention addresses these two limitations of conventional technology by greatly reducing design effort (because each connection is individually shielded) and fabrication time (by utilizing pick-and-place and/or wirebond-style assembly).

Other features and advantages of the invention are apparent from the following description, and from the claims.

### DESCRIPTION OF DRAWINGS

FIG. 1 is an electronic system including miniature coaxial wires.

FIG. 2 is a bare die based electronic system including miniature coaxial wires.

FIG. 3 is a first attachment strategy for the electronic system of FIG. 2.

FIG. 4 is a second attachment strategy for the electronic system of FIG. 2.

FIG. 5 is a third attachment strategy for the electronic system of FIG. 2.

FIG. 6 is a packaged component based electronic system including miniature coaxial wires.

FIG. 7 is a first attachment strategy for the electronic system of FIG. 6.

FIG. 8 is a second attachment strategy for the electronic system of FIG. 6.

FIG. 9 is a third attachment strategy for the electronic system of FIG. 6.

FIG. 10 is a through-via-perforated board based electronic system including miniature coaxial wires.

FIG. 11 is a first attachment strategy for the electronic system of FIG. 10.

FIG. 12 is a cross-sectional view of a miniature coaxial wire for power distribution.

FIG. 13 is a cross-sectional view of a miniature coaxial wire for signal distribution.

FIGS. 14a-14h show a bead-based miniature coaxial wire fabrication method.

FIGS. 15-17 show a fixture for fabrication of miniature coaxial wire.

FIGS. 18a-18e show a fixture-based miniature coaxial wire fabrication method.

FIGS. 19a-19i show a MEMS-based miniature coaxial wire fabrication method.

FIG. 20a and FIG. 20b show two views of the apparatus for feeding and layer removal of coaxial wires.

FIG. 21 shows transverse motion of rotating shafts.

FIG. 22a and FIG. 22b show the spinning cutting blade.

FIGS. 23a and 23b show the removal of layers from a coaxial wire using the apparatus.

FIG. 24 shows another embodiment of the apparatus.

FIG. 25 is a spool-based miniature coaxial wire attachment device.

FIG. 26 is a wire stripper of the device of FIG. 25.

FIG. 27 shows welding tips of the device of FIG. 25.

FIG. 28 shows shield attachment strategies employed by the device of FIG. 25.

### DESCRIPTION

### 1 Miniature Multi-Wire System

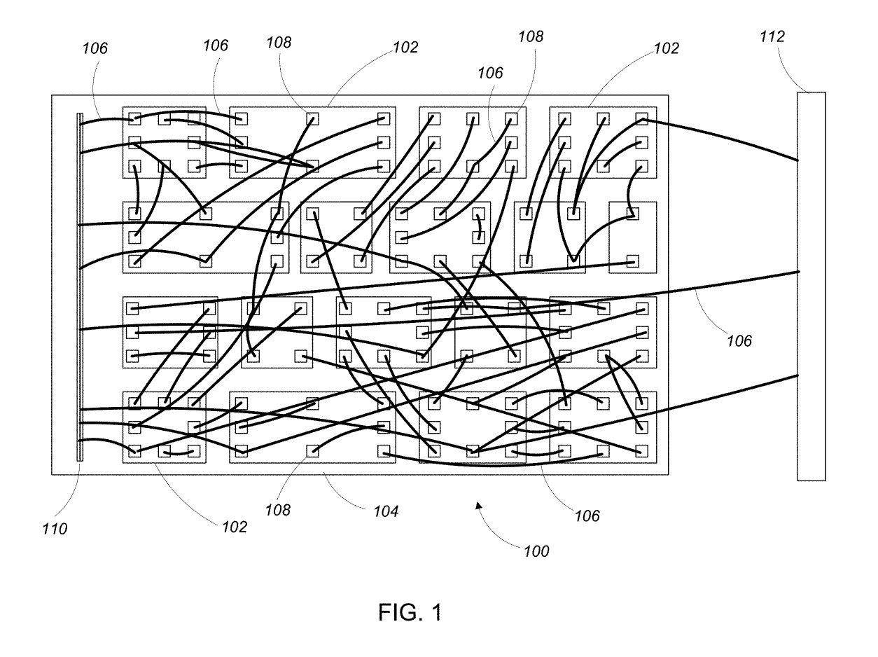

Referring to FIG. 1, an electronic system 100 replaces conductive traces and vias used to connect electrical components on conventional printed circuit boards with a miniature coaxial wiring system. The electronic system 100 includes a number of electronic components 102 (packaged integrated circuits, surface mountable ball grid array packaged integrated circuits, bare integrated circuits, etc.) attached to a substrate 104. Miniature coaxial wires 106 are used to connect connection points 108 (e.g., contact pads, solder balls of a ball grid array, etc.) on the electronic components 102 to connection points associated with a power supply 110, external devices 112, and to other connection points 108 on the same or other electronic components 102.

Given the large variation in electronic components available to engineers, a number of different strategies are employed to attach electronic components, to connection points associated with power supplies, external devices, and connection points on the same or other components, as is described in greater detail below.

### 1.1 Bare Die Based Miniature Multi-Wire System

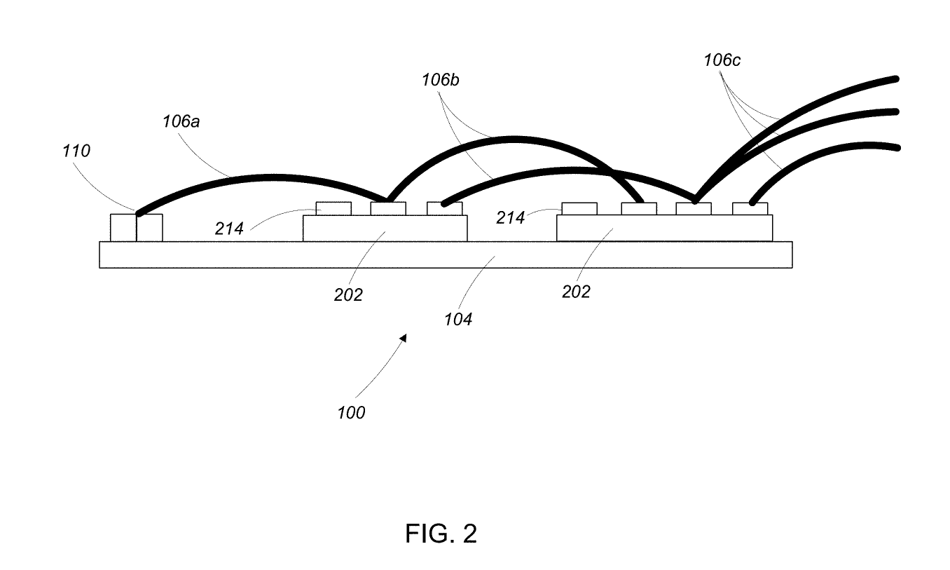

Referring to FIG. 2, in some examples, the electronic system 100 includes a number of bare dies (or ‘dice’) 202 attached to the substrate 104 (e.g., using an adhesive). Surfaces of the bare dies 202 facing away from the substrate 104 include contact pads 214 that are configured to be connected to one or more other connection points, external devices, and/or connection points associated with the power supply 110 using miniature coaxial wires 106 (as is described in greater detail below). For example, in the simple schematic diagram of FIG. 2, one or more first miniature coaxial wires 106a connect contact pads 214 of the bare dies 202 to connection points associated with the power supply 110, one or more second miniature coaxial wires 106b connect contact pads 214 of the bare dies 202 to other contact pads of the bare dies 202, and one or more third miniature coaxial wires 106c connect contact pads 214 of the bare dies 202 to one or more external devices or components.

### 1.1.1 Bare Die Attachment Strategy

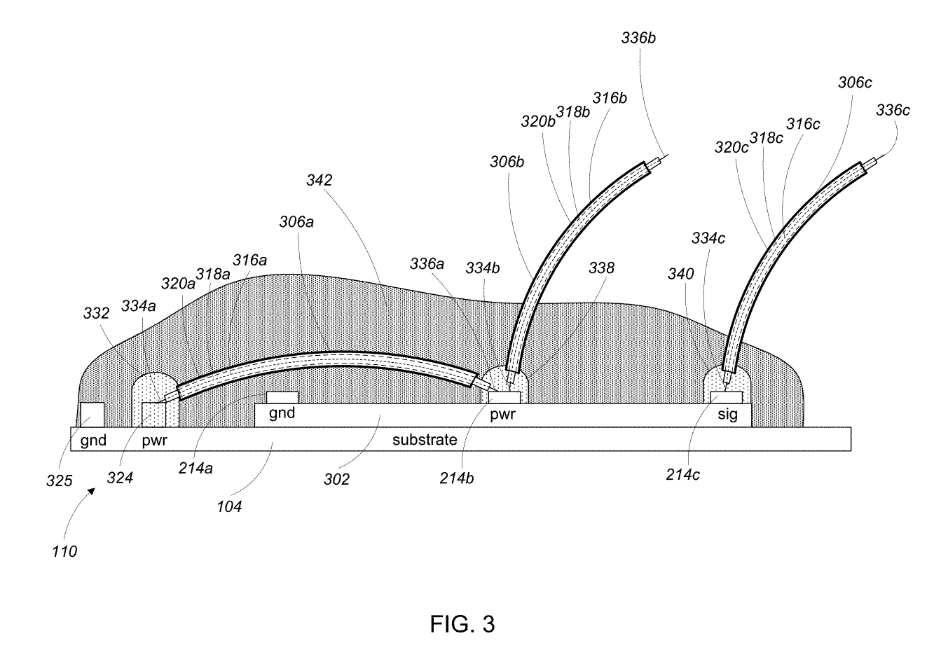

Referring to FIG. 3, a particular bare die 302 is attached to the substrate 104 and has its contact pads 214 connected to the power supply 110 using miniature coaxial wires according to an attachment strategy. The contact pads 214 are also connected to external devices (not shown) and to other connection points on other electronic components (not shown) using miniature coaxial wires according to the attachment strategy.

In the configuration of FIG. 3, there are three miniature coaxial wires 306 including a first miniature coaxial wire 306a, a second miniature coaxial wire 306b, and a third miniature coaxial wire 306c. The bare die 302 includes a ground (‘gnd’) contact pad 214a, a power (‘pwr’) contact pad 214b, and a signal (‘sig’) contact pad 214c.

In general, each of the miniature coaxial wires 306 includes a conductive inner core 316, an insulating layer 318, and a conductive outer shield 320. The conductive inner cores 316 of the miniature coaxial wires 306 are attached to contact pads 214 or other connection points 108 (e.g., a power (‘pwr’) connection point 324 associated with the power supply 110) and the conductive outer shield layers 320 of the miniature coaxial wires 106 are attached to a ‘gnd’ connection point 325 associated with the power supply 110, all while ensuring that the ‘gnd’ connection point 325 and the ‘pwr’ connection point 324 associated with the power supply 110 are not electrically connected (i.e., short circuited).

A first exposed portion 334a of the conductive inner core 316a of the first miniature coaxial wire 306a is attached to the ‘pwr’ connection point 324 associated with the power supply 110 and a second exposed portion 336a of the conductive inner core 316a of the first miniature coaxial wire 306a is attached to the ‘pwr’ contact pad 214b of the bare die 302. A first exposed portion 334b of the conductive inner core 316b of the second miniature coaxial wire 306b is attached to the ‘pwr’ contact pad 214b and a second exposed portion 336b of the conductive inner core 316b of the second miniature coaxial wire 306b is attached to another connection point or external device (not shown). A first exposed portion 334c of the conductive inner core 316c of the third miniature coaxial wire 306c is attached to the ‘sig’ contact pad 214c and a second exposed portion 336c of the conductive inner core 316c of the third miniature coaxial wire 306c is attached to another connection point or external device (not shown). In some examples, the connections between the conductive inner cores 316 and the various connection points are established using welding techniques (e.g., ultrasonic welding, electron beam welding, cold welding, laser welding, resistance welding, thermosonic capillary welding, or thermosonic wedge/peg welding) or soldering techniques.

Each connection between an exposed portion 334,336 of a conductive inner core 316 and a connection point is fully encased in an insulator. In the example of FIG. 3, the connection between the first exposed portion 334a of the conductive inner core 316a of the first miniature coaxial wire 306a and the ‘pwr’ connection point 324 is fully encased in a first insulator 332.

The connection between the second exposed portion 336a of the conductive inner core 316a of the first miniature coaxial wire 306a and the ‘pwr’ contact pad 214b is fully encased in a second insulator 338. The connection between the first exposed portion 334b of the conductive inner core 316b of the second miniature coaxial wire 306b and the ‘pwr’ contact pad 214b is also fully encased in the second insulator 338.

The connection between the first exposed portion 334c of the conductive inner core 316c of the third miniature coaxial wire 306c and the ‘sig’ contact pad 214c is fully encased in a third insulator 340.

In general, in the example of FIG. 3, the term “fully encased” by insulating material relates to both the exposed portion 334,336 of the conductive inner core 316 and the contact pad 214 or other connection point 108 being entirely covered by the insulating material, without any portion of the conductive inner core 316 and the contact pad 214 or other connection point 108 being left exposed. In general, an exposed part of the insulating layer 318 is also encased in the insulating material and a part of the conducting shield layer 320 may also be encased in the insulating material. One example of a suitable insulating material is a polyimide material. Of course, other suitable insulating polymers or other materials can be used.

A mass of conductive material 342 is deposited on the bare die 302 and the substrate 104, covering the ground (‘gnd’) connection point 325 associated with the power supply 110, the first insulator 332, the ‘gnd’ contact pad 214a of the bare die 302, the second insulator 338, and the third insulator 340. The mass of conductive material 342 establishes an electrical connection between the ‘gnd’ connection point 325 and the ‘gnd’ contact pad 214a of the bare die 302. The insulators 332, 338, 340 prevent a short circuit between the ‘gnd’ connection point 325 and the ‘pwr’ connection point 324, the ‘pwr’ contact pad 214b, or the ‘sig’ contact pad 214c from occurring.

The mass of conductive material 342 also fully encases the conductive shield layer 320a of the first miniature coaxial wire 306a, partially encases the conductive shield layer 320b of the second miniature coaxial wire 306b, and partially encases the conductive shield layer 320c of the third miniature coaxial wire 306c. As such, the mass of conductive material 342 is a ‘connector’ establishing an electrical connection between the ‘gnd’ connection point 325 and the conductive shield layers 320 of the miniature coaxial wires 306.

In general, the mass of conductive material 342 encases as much of the conductive shield layer as possible for all of the miniature coaxial wires. In some examples, there are 3 scenarios for in which the mass of conductive material 342 is used: (1) the mass 342 encases everything including all of the wires, insulation, chips, and power/gnd. (2) the mass 342 encases each chip 302 individually, making connection to a ground rail 325, and (3) a combination of (1) and (2).

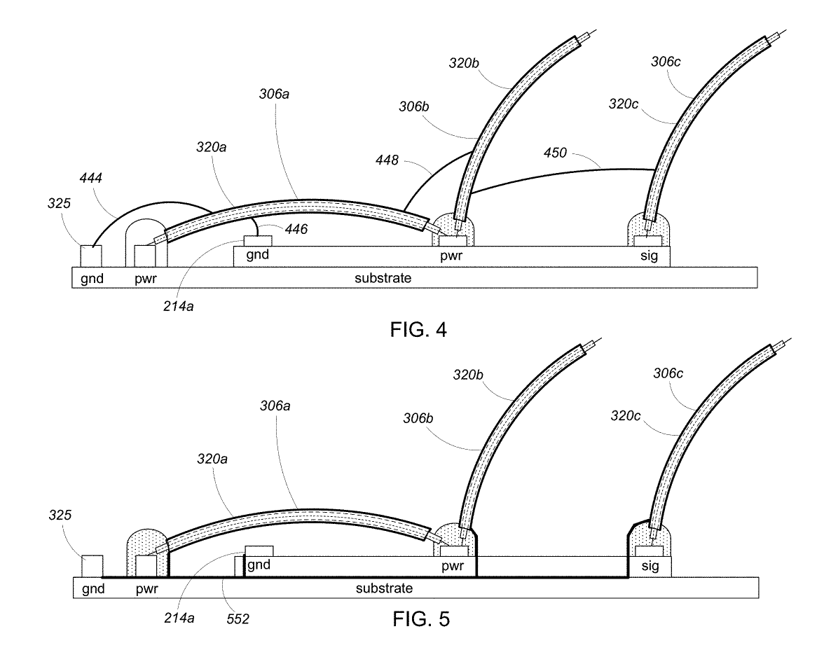

Referring to FIG. 4, in some examples fine wires (e.g., of the type used in wire bonding techniques) are used instead of the mass of conductive material 342 of FIG. 3 to establish an electrical connection between the ‘gnd’ connection point 325, the ‘gnd’ contact pad 214a of the bare die 302, and the conductive shield layers 320 of the miniature coaxial wires 306.

In particular, a first fine wire 444 connects the ‘gnd’ connection point 325 to the conductive shield layer 320a of the first miniature coaxial wire 306a. A second fine wire 446 connects the conductive shield layer 320a of the first miniature coaxial wire 306a to the ‘gnd’ contact pad 214a of the bare die 302. A third fine wire 448 connects the conductive shield layer 320a of the first miniature coaxial wire 306a to the conductive shield layer 320b of the second miniature coaxial wire 306b. A fourth fine wire 450 connects the conductive shield layer 320b of the second miniature coaxial wire 306b to the conductive shield layer 320c of the third miniature coaxial wire 306c.

Referring to FIG. 5, in some examples, one or more printed wires are used instead of the mass of conductive material 342 of FIG. 3 to establish an electrical connection between the ‘gnd’ connection point 325, the ‘gnd’ contact pad 214a of the bare die 302, and the conductive shield layers 320 of the miniature coaxial wires 306.

In particular, a printed wire 552 connects the ‘gnd’ connection point 325 to the conductive shield layer 320a of the first miniature coaxial wire 306a, the ‘gnd’ contact pad 214a of the bare die 302, the conductive shield layer 320b of the second miniature coaxial wire 306b, and the conductive shield layer 320c of the third miniature coaxial wire 306c.

### 1.2 Package Based Miniature Multi-Wire System

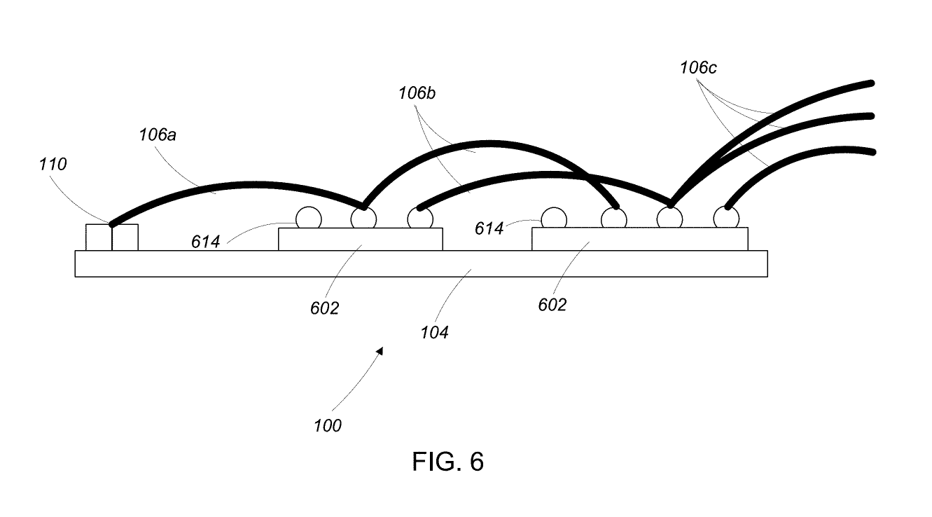

Referring to FIG. 6, in some examples, the electronic system 100 includes a number of packaged components 602 (e.g., ball grid array components, dual in-line packaged components, surface mount components, chip carriers, etc.) attached to the substrate 104 (e.g., using an adhesive). Surfaces of the packaged components 602 facing away from the substrate 104 include solder balls 614 (or other packaged component-specific connection points) that are configured to be connected to one or more other connection points, external devices, and/or the power supply 110 using miniature coaxial wires 106 (as is described in greater detail below). For example, in the simple schematic diagram of FIG. 6, one or more first miniature coaxial wires 106a connect solder balls 614 of the packaged components 602 to the power supply 110, one or more second miniature coaxial wires 106b connect solder balls 614 of the packaged components 602 to other solder balls 614 of the packaged components 602, and one or more third miniature coaxial wires 106c connect solder balls 614 of the packaged components 602 to one or more external devices or components (not shown).

### 1.2.1 Packaged Component Attachment Strategy

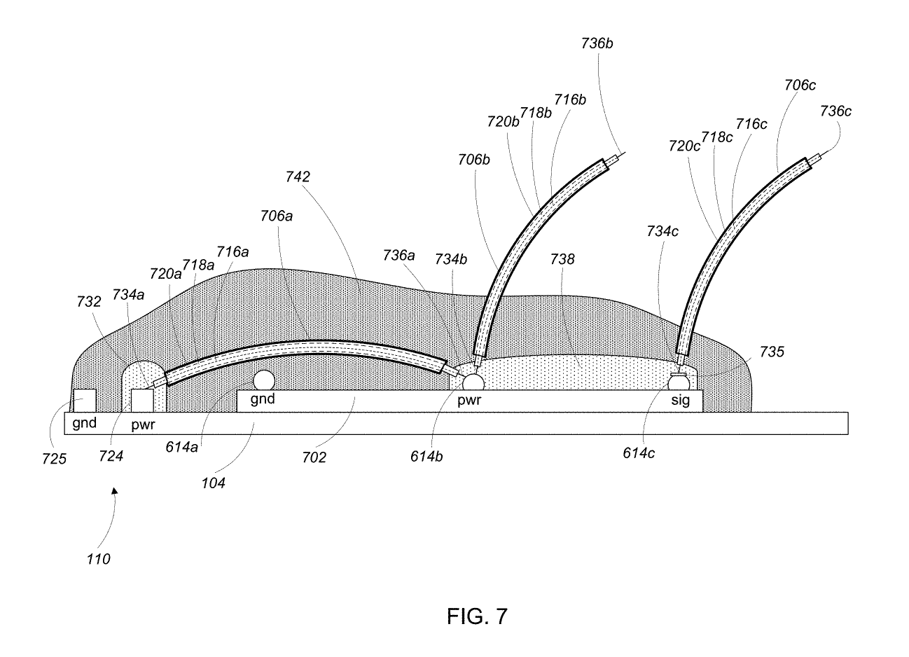

Referring to FIG. 7, a particular packaged component 702 is attached to the substrate 104 and has its solder balls 614 connected to the power supply 110 using miniature coaxial wires according to an attachment strategy. The solder balls 614 are also connected to external devices (not shown) and to other connection points on other electronic components (not shown) using miniature coaxial wires according to an attachment strategy.

In the configuration of FIG. 7, there are three miniature coaxial wires including a first miniature coaxial wire 706a, a second miniature coaxial wire 706b, and a third miniature coaxial wire 706c. The packaged component 702 includes a ground (‘gnd’) solder ball 614a, a power (‘pwr’) solder ball 614b, and a signal (‘sig’) solder ball 614c.

In general, each of the miniature coaxial wires 706 includes a conductive inner core 716, an insulating layer 718, and a conductive outer shield 720. The conductive inner cores 716 of the miniature coaxial wires 706 are attached to contact pads 614 or other connection points 108 (e.g., a power (‘pwr’) connection point 724 associated with the power supply 110) and the conductive outer shield layers 716 of the miniature coaxial wires 706 are attached to the ‘gnd’ connection point 725 associated with the power supply 110, all while ensuring that the ‘gnd’ connection point 725 and the ‘pwr’ connection point 724 associated with the power supply are not electrically connected (i.e., short circuited).

A first exposed portion 734a of the conductive inner core 716a of the first miniature coaxial wire 706a is attached to the ‘pwr’ connection point 724 associated with the power supply 110 and a second exposed portion 736a of the conductive inner core 716a of the first miniature coaxial wire 706a is attached to the ‘pwr’ solder ball 614b of the packaged component 702. A first exposed portion 734b of the conductive inner core 716b of the second miniature coaxial wire 706b is attached to the ‘pwr’ solder ball 614b and a second exposed portion 736b of the conductive inner core 716b of the second miniature coaxial wire 706b is attached to another connection point or external device (not shown). A first exposed portion 734c of the conductive inner core 716c of the third miniature coaxial wire 706c is attached to the ‘sig’ solder ball 614c and a second exposed portion 736c of the conductive inner core 716c of the third miniature coaxial wire 706c is attached to another connection point or external device (not shown). In some examples, the connections between the conductive inner cores 716 and the various connection points are established using welding techniques (e.g., ultrasonic welding, electron beam welding, cold welding, laser welding, resistance welding, thermosonic capillary welding, or thermosonic wedge/peg welding) or soldering techniques. Note that, in some examples, one or more interposer pads 735 are attached to the solder balls 614 to facilitate a reliable connection between the exposed portions 734,736 of the conductive inner cores 716 and the solder balls 614.

Each connection between an exposed portion 734,736 of a conductive inner core 716 and a connection point is fully encased in an insulating material. In the example of FIG. 7, the connection between the first exposed portion 734a of the conductive inner core 716a of the first miniature coaxial wire 706a and the ‘pwr’ connection point 724 is fully encased in a first insulator 732.

The connection between the second exposed portion 736a of the conductive inner core 716a of the first miniature coaxial wire 706a and the ‘pwr’ solder ball 614b is fully encased in a second insulator 738. The connection between the first exposed portion 734b of the conductive inner core 716b of the second miniature coaxial wire 706b and the ‘pwr’ solder ball 614b is also fully encased in the second insulator 738. In this example, the connection between the first exposed portion 734c of the conductive inner core 716c of the third miniature coaxial wire 706c and the ‘sig’ solder ball 614c is also fully encased in the second insulator 738.

As was the case in previous examples, the term “fully encased” by insulating material relates to both the exposed portion 734,736 of the conductive inner core 716 and the solder ball 614 or other connection point 108 being entirely covered by the insulating material, without any portion of the conductive inner core 716 and the solder ball 614 or other connection point 108 being left exposed. In general, an exposed part of the insulating layer 718 of the miniature coaxial wire 706 is also encased in the insulating material and a part of the conducting shield layer 720 of the miniature coaxial wire 706 may also be encased in the insulating material. One example of a suitable insulating material is a polyimide material. Of course, other suitable insulating polymers can be used.

A mass of conductive material 742 is deposited on the packaged component 702 and the substrate 104, covering the ground (‘gnd’) connection point 725 associated with the power supply 110, the first insulator 732, the ‘gnd’ solder ball 614a of the packaged component 702 and the second insulator 738. The mass of conductive material 742 establishes an electrical connection between the ‘gnd’ connection point 725 and the ‘gnd’ solder ball 614a of the packaged component 702. The insulators 732, 738 prevent a short circuit between the ‘gnd’ connection point 725 and the ‘pwr’ connection point 724, the ‘pwr’ solder ball 614b, or the ‘sig’ contact pad 614c from occurring.

The mass of conductive material 742 also fully encases the conductive shield layer 720a of the first miniature coaxial wire 706a, partially encases the conductive shield layer 720b of the second miniature coaxial wire 706b, and partially encases the conductive shield layer 720c of the third miniature coaxial wire 706c. As such, the mass of conductive material 742 is a ‘connector,’ establishing an electrical connection between the ‘gnd’ connection point 725 and the conductive shield layers 720 of the miniature coaxial wires 706.

In general, the mass of conductive material 742 encases as much of the conductive shield layer as possible for all of the miniature coaxial wires. In some examples, there are 3 scenarios for in which the mass of conductive material 742 is used: (1) the mass 742 encases everything including all of the wires, insulation, chips, and power/gnd. (2) the mass 742 encases each component 702 individually, making connection to a ground rail 725, and (3) a combination of (1) and (2).

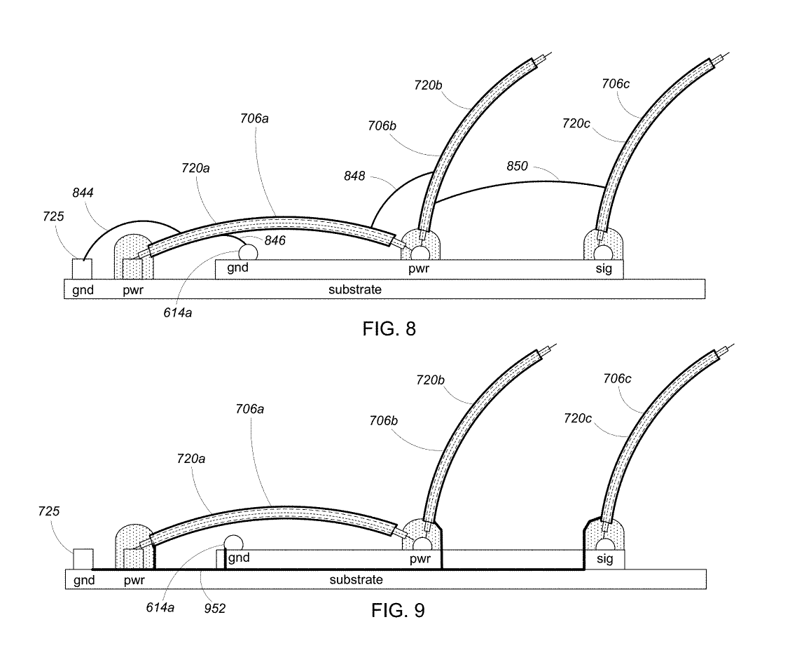

Referring to FIG. 8, in some examples fine wires (e.g., of the type used in wire bonding techniques) are used instead of the mass of conductive material 742 of FIG. 7 to establish an electrical connection between the ‘gnd’ connection point 725, the ‘gnd’ solder ball 614a of the packaged component 702, and the conductive shield layers 720 of the miniature coaxial wires 706.

In particular, a first fine wire 844 connects the ‘gnd’ connection point 725 to the conductive shield layer 720a of the first miniature coaxial wire 706a. A second fine wire 846 connects the conductive shield layer 720a of the first miniature coaxial wire 706a to the ‘gnd’ solder ball 614a of the packaged component 702. A third fine wire 848 connects the conductive shield layer 720a of the first miniature coaxial wire 706a to the conductive shield layer 720b of the second miniature coaxial wire 706b. A fourth fine wire 850 connects the conductive shield layer 720b of the second miniature coaxial wire 706b to the conductive shield layer 720c of the third miniature coaxial wire 706c.

Referring to FIG. 9, in some examples, one or more printed wires are used instead of the mass of conductive material 742 of FIG. 7 to establish an electrical connection between the ‘gnd’ connection point 725, the ‘gnd’ solder ball 614a of the packaged component 702, and the conductive shield layers 720 of the miniature coaxial wires 706.

In particular, a printed wire 952 connects the ‘gnd’ connection point 725 to the conductive shield layer 720a of the first miniature coaxial wire 706a, the ‘gnd’ solder ball 614a of the packaged component 702, the conductive shield layer 720b of the second miniature coaxial wire 706b, and the conductive shield layer 720c of the third miniature coaxial wire 706c.

### 1.3 Through-Via-Perforated (TVP) Board Based Miniature Multi-Wire System

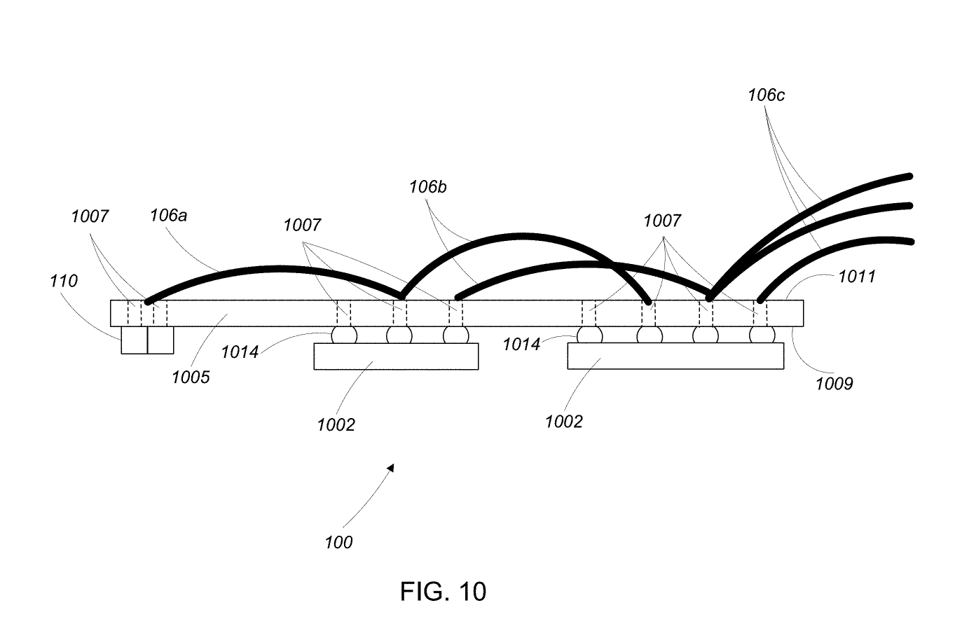

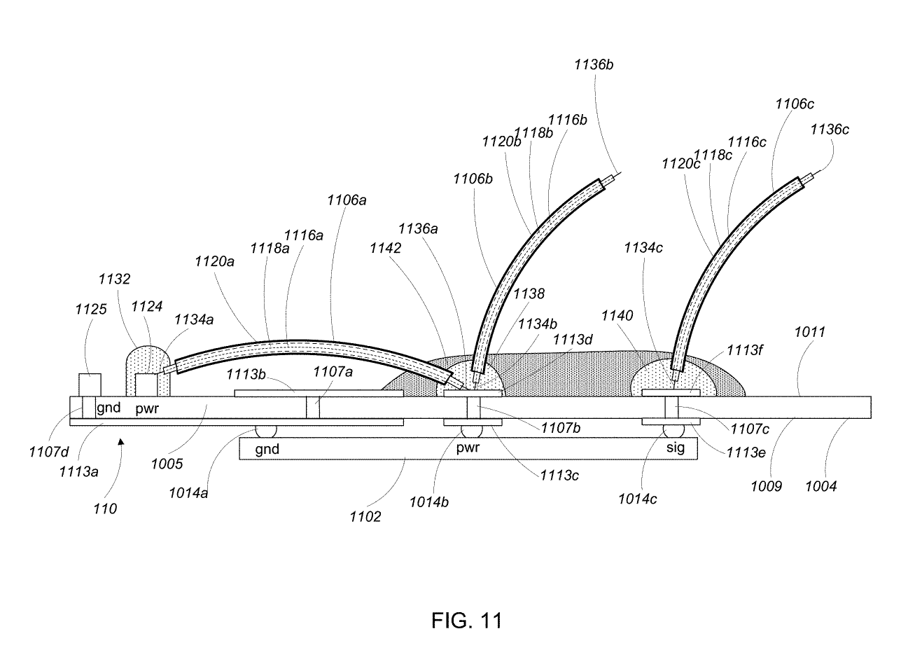

Referring to FIG. 10, in some examples, the electronic system 100 includes a number of components such as bare dies or packaged components 1002 (e.g., ball grid array components, dual in-line packaged components, surface mount components, chip carriers, etc.) assembled on a Through-Via-Perforated (TVP) board 1004. In general, a TVP board 1004 includes an insulating substrate 1005 with a number of vias 1007 extending therethrough. The vias 1007 are filled with a conductive material (e.g., solder) and may be connected to electrically conductive contact pads (see FIG. 11) or plates on a first side 1009 and/or a second side 1011 of the substrate 1005. The packaged components 1002 (or in some examples, bare dies) are positioned on the first side 1009 of the TVP board 1004 and include solder balls 1014 (or other packaged component-specific connection points) that are aligned with and joined (e.g., soldered) to the vias 1007 and their associated electrically conductive contact pads or plates.

On the second side 1011 of the TVP board 1004, the vias 1007 and their associated electrically conductive contact pads or plates are configured to be connected to one or more other connection points (e.g., vias), external devices, and/or the power supply 110 using miniature coaxial wires 106 (as is described in greater detail below). For example, in the simple schematic diagram of FIG. 10, one or more first miniature coaxial wires 106a connect vias 1007 connected to the packaged components 1002 to the power supply 110, one or more second miniature coaxial wires 106b connect vias 1007 connected to the packaged components 1002 to other vias 1007 of the packaged components 1002, and one or more third miniature coaxial wires 106c connect vias connected to the packaged components 1002 to one or more external devices or components (not shown).

### 1.3.1 Through-Via-Perforated Board Attachment Strategy

Referring to FIG. 11, a TVP board 1004 includes a power supply 110 and four vias. The power supply has a power (‘pwr’) connection point 1124 and a ground (‘gnd’) connection point 1125. A first via 1107d of the TVP board 1004 is connected to the ‘gnd’ connection point 1125 on the second side 1011 of the TVP board 1004 and to a first electrically conductive plate 1113a on the first side 1009 of the TVP board 1004. As a result, electrical signals can travel between the ‘gnd’ connection point 1125 and the first electrically conductive plate 1113a by way of the first via 1107d.

A second via 1107a is connected to the first electrically conductive plate 1113a on the first side 1009 of the TVP board 1004 and to a second electrically conductive plate 1113b on the second side 1011 of the TVP board 1004. As a result, electrical signals can travel between the first electrically conductive plate 1113a and the second electrically conductive plate 1113b by way of the second via 1107a.

A third via 1107b is connected to a third electrically conductive plate 1113c on the first side 1009 of the TVP board 1004 and to a fourth electrically conductive plate 1113d on the second side 1011 of the TVP board 1004. As a result, electrical signals can travel between the third electrically conductive plate 1113c and the fourth electrically conductive plate 1113d by way of the third via 1107b.

A fourth via 1107d is connected to a fifth electrically conductive plate 1113e on the first side 1009 of the TVP board 1004 and to a sixth electrically conductive plate 1113f on the second side 1011 of the TVP board. As a result, electrical signals can travel between the fifth electrically conductive plate 1113e and the sixth electrically conductive plate 1113f by way of the fourth via 1107c.

A particular packaged component 1102 is attached to the first side 1009 of the TVP board 1004 with each of its solder balls 1014 attached to a via 1007 by way of an electrically conductive plate 1113. In particular, a ground ‘gnd’ solder ball 1014a is attached to the first electrically conductive plate 1113a (and is therefore connected to the first via 1107d and the second via 1107a). A power ‘pwr’ solder ball 1014b is attached to the third electrically conductive plate 1113c (and is therefore connected to the third via 1107b). A signal ‘sig’ solder ball 1014c is attached to the fifth electrically conductive plate 1113e (and is therefore connected to the fourth via 1107c). It is noted that connections from the components to the vias don't necessarily need to use a solder ball. In some examples, solder is used for packaged components and other connection types are used for die (e.g. Cu oxide bonds or C4 bumps).

With the packaged component 1102 attached to the TVP board 1004, an attachment strategy is employed to connect the vias 1107 to the power supply 110, external devices 112 (not shown), and to other connection points 108 on other electronic components (not shown) using miniature coaxial wires.

In general, each of the miniature coaxial wires 1106 includes a conductive inner core 1116, an insulating layer 1118, and a conductive outer shield 1120. The conductive inner cores 1116 of the miniature coaxial wires 1106 are connected to contact pads 1014 or other connection points 108 (e.g., the power (‘pwr’) connection point 1124 associated with the power supply 110) and the conductive outer shield layers 1120 of the miniature coaxial wires 1106 are connected to the ‘gnd’ connection point 1125 associated with the power supply 110, all while ensuring that the ‘gnd’ connection point 1125 and the ‘pwr’ connection point 1124 associated with the power supply are not electrically connected (i.e., short circuited).

In the configuration of FIG. 11, there are three miniature coaxial wires including a first miniature coaxial wire 1106a, a second miniature coaxial wire 1106b, and a third miniature coaxial wire 1106c

A first exposed portion 1134a of the conductive inner core 1116a of the first miniature coaxial wire 1106a is attached to the ‘pwr’ connection point 1124 associated with the power supply 110 and a second exposed portion 1136a of the conductive inner core 1116a of the first miniature coaxial wire 1106a is attached to the fourth electrically conductive plate 1113d (and therefore to the ‘pwr’ solder ball 1014b of the packaged component 1102 by way of the third via 1107b and the third electrically conductive plate 1113c).

A first exposed portion 1134b of the conductive inner core 1116b of the second miniature coaxial wire 1106b is attached to the fourth electrically conductive plate 1113d (and therefore to the ‘pwr’ solder ball 1014b of the packaged component 1102 by way of the third via 1107b and the third electrically conductive plate 1113c). A second exposed portion 1136b of the conductive inner core 1116b of the second miniature coaxial wire 1106b is attached to another connection point or external device (not shown).

A first exposed portion 1134c of the conductive inner core 1116c of the third miniature coaxial wire 1106c is attached to the sixth electrically conductive plate 1113f (and therefore to the ‘sig’ solder ball 1014c of the packaged component 1102 by way of the fifth via 1107c and the third electrically conductive plate 1113e). A second exposed portion 1136c of the conductive inner core 1116c of the third miniature coaxial wire 1106c is attached to another connection point or external device (not shown).

In some examples, the connections between the conductive inner cores 716 and the various connection points are established using welding techniques (e.g., ultrasonic welding, electron beam welding, cold welding, laser welding, resistance welding, thermosonic capillary welding, or thermosonic wedge/peg welding) or soldering techniques.

Each connection between an exposed portion 1134,1136 of a conductive inner core 1116 and a connection point is fully encased in an insulating material.

In the example of FIG. 11, the connection between the first exposed portion 1134a of the conductive inner core 1116a of the first miniature coaxial wire 1106a and the ‘pwr’ connection point 1124 is fully encased in a first insulator 1132. The connection between the second exposed portion 1136a of the conductive inner core 1116a of the first miniature coaxial wire 1106a and the fourth electrically conductive plate 1113d is fully encased in a second insulator 1138.

The connection between the first exposed portion 1134b of the conductive inner core 1116b of the second miniature coaxial wire 1106b and the fourth electrically conductive plate 1113d is fully encased in the second insulator 1138.

The connection between the first exposed portion 1134c of the conductive inner core 1116c of the third miniature coaxial wire 1106c and the sixth electrically conductive plate 1113f is fully encased in a third insulator 1140.

As was the case in previous examples, the term “fully encased” by insulating material relates to both the exposed portion 1134/1136 of the conductive inner core 1116 and the solder ball 1014 or other connection point 108 being entirely covered by the insulating material, without any portion of the conductive inner core 1116 and the solder ball 1014 or other connection point 108 being left exposed. In general, an exposed part of the insulating layer 1118 of the miniature coaxial wire 1106 is also encased in the insulating material and a part of the conducting shield layer 1120 of the miniature coaxial wire 1106 may also be encased in the insulating material. One example of a suitable insulating material is a polyimide material. Of course, other suitable insulating polymers can be used.

A mass of conductive material 1142 is deposited on the second side 1011 of the TVP board 1004, partially covering the second electrically conductive plate 1113b, the first insulator 1138, and the second insulator 1140. The mass of conductive material 742 also partially encases the conductive shield layer 1120a of the first miniature coaxial wire 1106a, partially encases the conductive shield layer 1120b of the second miniature coaxial wire 1106b, and partially encases the conductive shield layer 1120c of the third miniature coaxial wire 1106c. As such, the mass of conductive material 1142 is a ‘connector,’ establishing an electrical connection between the ‘gnd’ connection point 1125 and the conductive shield layers 1120 of the miniature coaxial wires 1106 (by way of the mass of conductive material 1142, the second electrically conductive plate 1113b, the second via 1107a, the first electrically conducting plate 1113a, and the first via 1107d).

The insulators 1132, 1138, 1140 prevent a short circuit between the ‘gnd’ connection point 1125 and the ‘pwr’ connection point 1124, the ‘pwr’ solder ball 1014b, or the ‘sig’ contact pad 1014c from occurring.

In general, the mass of conductive material 1142 encases as much of the conductive shield layer as possible for all of the miniature coaxial wires. In some examples, the mass of conductive material 1142 extends to encase the ‘gnd’ connection point 1125. In some examples, the mass of conductive material 1142 coats substantially the entire second side 1011 of the TVP board 1004.

### 1.4 Miscellaneous

In some examples, the mass of conductive material described in the examples above is a metallic material that is deposited by flowing the material (e.g., flowing melted solder). In some examples, the mass of conductive material described in the examples above is a metallic material that is deposited by spray coating the material. In some examples, the mass of conductive material described in the examples above is a metallic material that is deposited by vapor depositing the material. In some examples, the mass of conductive material described in the examples above is a metallic material that is deposited by sputtering the material. In some examples, the mass of conductive material described in the examples above is a metallic material that is deposited by plating (e.g., electroplating or electroless plating) the material.

In some examples, insulating materials are dispensed from a needle or using a jet printing technique. In some examples, the conductive mass of material is dispensed from a needle or by using a jet printing technique. In some examples, the insulating materials include epoxy materials to ensure that the bond of the wire to the connection point is stronger than the wire itself.

In some examples, the electrically insulating material described in the examples above is deposited by flowing the material into place. In some examples, the electrically insulating material described in the examples above is deposited by vapor depositing the material into place. In some examples, the electrically insulating material includes a polymeric material. In some examples, the electrically insulating material described in the examples above is deposited by aerosol jetting the material into place.

In some examples, electrically conductive connections are established using conductive adhesives.

In some examples, miniature multi-wire systems include combinations of two or more of the configurations and attachments strategies described above.

### 2 Miniature Coaxial Wires

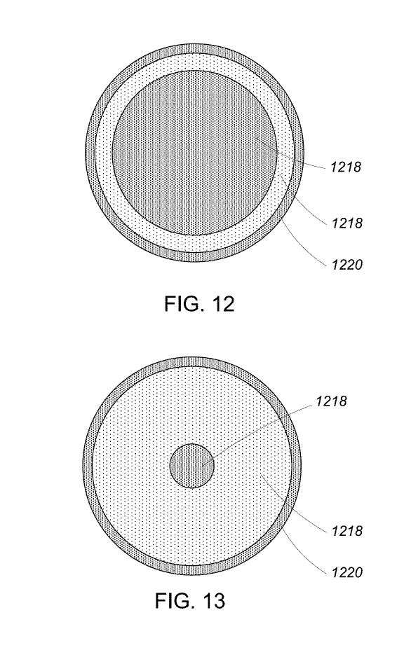

Referring to FIGS. 12 and 13, in some examples, the miniature coaxial wires used in the above-described systems have specific properties based on the type of signal that they are designed to carry. Examples of such miniature coaxial wires include miniature coaxial wires for power distribution and miniature coaxial wires for signal distribution.

### 2.1 Miniature Coaxial Wires for Power Distribution

Referring to FIG. 12, a cross-sectional view of a miniature coaxial wire for power distribution includes an electrically conductive shield layer 1220, an electrically insulating layer 1218, and an electrically conductive core 1216. Current is carried down the electrically conductive core 1216 and returns via the electrically conductive shield 1220.

In general, the miniature coaxial wire for power distribution is designed to have low resistance, low inductance, and low impedance, and high capacitance. In general, the resistance, inductance, impedance, and capacitance values of the miniature coaxial wires vary widely depending on the chips to which the wires are being attached. Inductance and resistance should be as close to zero as possible (at least in the case of power miniature coaxial wires). Theoretical limits (simulated) show that the inductance of the wires can be as low as 20 pH/mm. In one example, a miniature coaxial wire has an impedance in the milliohm range.

To achieve these properties, the electrically conductive core occupies a large percentage of the cross-sectional area of the wire. For example, given a 15 um diameter miniature coaxial wire for power distribution, the electrically conductive core 1216 has, for example, a 10 um diameter, the electrically conductive shield layer 1220 has the same cross-sectional area as the electrically conductive core 1216, and the electrically insulating layer 1218 has a thickness of 1 um.

In general, the thickness of the electrically conductive core 1216 is defined by the amount of power distributed to the chip. The thickness of the insulating layer 1218 is as small as possible to minimize impedance in the wire. In some examples, the electrically conductive shield layer 1220 is designed to be at least as conductive as the electrically conducive core 1216. In some examples, the electrically conductive core 1216 has a 127 um diameter when being used to connect packaged components and has a 11.4 um diameter when being used to make chip-level connections (i.e., bare die connections). In some examples, the insulating layer 1218 has a thickness in a range of 0.1 um to 5 um when being used to connect packaged components and has a thickness less than 1 um when being used to make chip-level connections.

2.2 Miniature Coaxial Wires for Signal Distribution

Referring to FIG. 13, a cross-sectional view of a miniature coaxial wire for signal distribution includes an electrically conductive shield layer 1320, an electrically insulating layer 1318, and an electrically conductive core 1316.

In general, the miniature coaxial wire for signal distribution is designed to have a resistance in a range of 30 to 75 Ohms. For example, certain miniature coaxial wires for signal distribution are designed to have a 50 Ohm resistance. The electrically insulating layer 1318 is thick relative to the electrically insulating layer of the miniature coaxial wire for power distribution and the diameter of the electrically conductive core 1316 is small relative to the electrically conductive core of the miniature coaxial wire for power distribution.

### 2.3 Miniature Coaxial Wire Fabrication

Given the small size of the miniature coaxial wires used in the systems described above, a number of non-conventional miniature coaxial wire fabrication techniques are used to make the wires.

### 2.3.1 Bead Based Fabrication

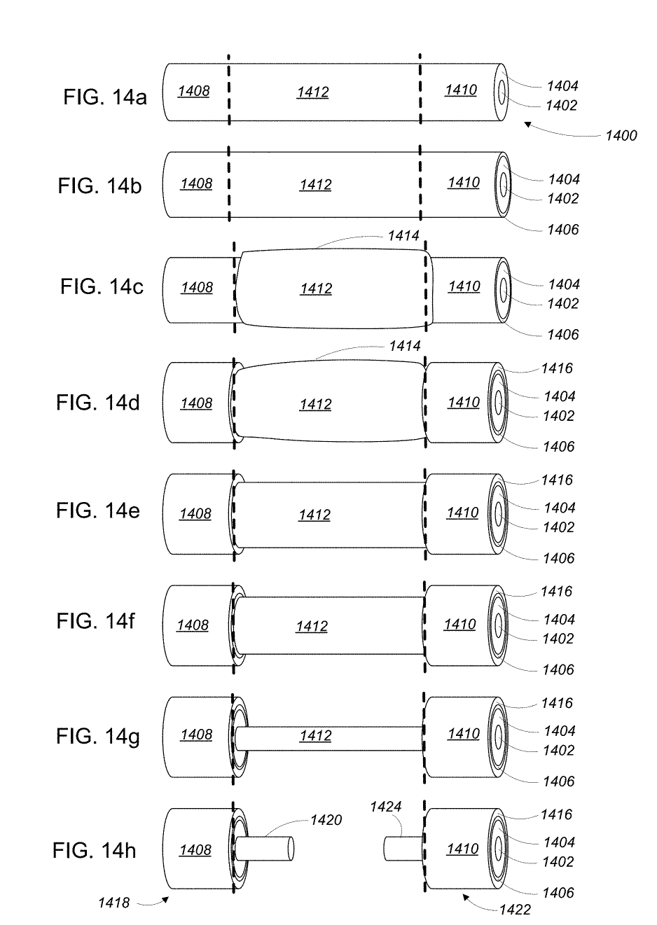

Referring to FIGS. 14a-14h a bead based miniature coaxial wire fabrication method fabricates two (or more) lengths of miniature coaxial wire, each length having a portion of its conductive inner core exposed.

Referring to FIG. 14a, the fabrication method begins by receiving a length of insulated wire 1400. The length of insulated wire includes an electrically conductive inner core 1402 surrounded by an electrically insulating layer 1404. To aid in the explanation of the fabrication method, the insulated wire 1400 is described as having three segments, a first segment 1408, a second segment 1410, and a third segment 1412 disposed between the first segment 1408 and the second segment 1410.

Referring to FIG. 14b, after receiving the length of insulated wire 1400, an adhesion layer 1406 is deposited on the electrically insulating layer 1404 over the length of insulated wire 1400 (i.e., on the first segment 1408, the second segment 1410, and the third segment 1412). In general, the adhesion layer serves to facilitate adhesion of an electroplated material to the insulated wire (as is described in detail below).

Referring to FIG. 14c, after deposition of the adhesion layer 1406, a masking bead 1414 is deposited on the adhesion layer 1406 in the third segment 1412. The masking bead 1414 prevents adhesion of an electroplated material to the third segment 1412. In some examples, the masking bead 1414 is formed of a polymeric material and is deposited by a needle, spray, sputter, or jet based deposition method.

Referring to FIG. 14d, after deposition of the masking bead 1414, an electrically conductive shield layer 1416 is deposited on the first segment 1408 and the second segment 1410 (but not the third segment 1412, due to the presence of the masking bead 1414).

Referring to FIG. 14e, after deposition of the electrically conductive shield layer 1416, the masking bead 1414 is removed from the third segment 1412. In some examples, the masking bead 1414 is removed using a laser cutting/etching procedure. In some examples, the masking bead 1414 is removed from the third segment 1412 using a chemical removal procedure, wherein the masking bead 1414 is formed form a photoresist or nail-polish like material and removal of the masking bead 1414 includes dipping the masking bead 1414 in a bath of photoresist remover or acetone. In some examples, the masking bead 1414 (and possibly a portion of the dielectric material) is thermally removed.

Referring to FIG. 14f, the adhesion layer 1406 is removed from the third segment 1412. In some examples, the adhesion layer 1406 is removed after removal of the masking bead 1414 from the third segment 1412. In some examples, the adhesion layer 1406 is removed at the same time that the masking bead 1414 is removed from the third segment 1412. In some examples, the adhesion layer 1406 is removed using a laser cutting/etching procedure. In some examples, the adhesion layer 1406 is removed using a wet etch (e.g., Au, Cu, Ti etchant chemistries).

Referring to FIG. 14g, the electrically insulating layer 1404 of the insulated wire 1400 is removed from the third segment 1412, exposing the electrically conductive core 1402 in the third segment 1412. In some examples, the electrically insulating layer 1404 is removed using a laser cutting/etching procedure. In some examples, the electrically insulating layer 1404 is thermally removed. In some examples, when the electrically insulating layer 1404 is particularly thin, the adhesion layer 1406 doesn't need to be explicitly removed.

Referring to FIG. 14h, the electrically conductive core 1402 in the third segment 1412 is bisected (e.g., using a wire cutter or a blade), creating a first length of miniature coaxial wire 1418 with a first exposed section 1420 of electrically conductive core 1402 and a second length of miniature coaxial wire 1422 with a second exposed section 1424 of electrically conductive core 1402.

In general, the procedure above can be used to generate any number of lengths of miniature coaxial wire from a length of insulated wire. Furthermore, the lengths of the miniature coaxial wires generated by the fabrication procedure can be specified (by bead placement) to meet the needs of a given application.

### 2.3.2 Fixture Based Fabrication

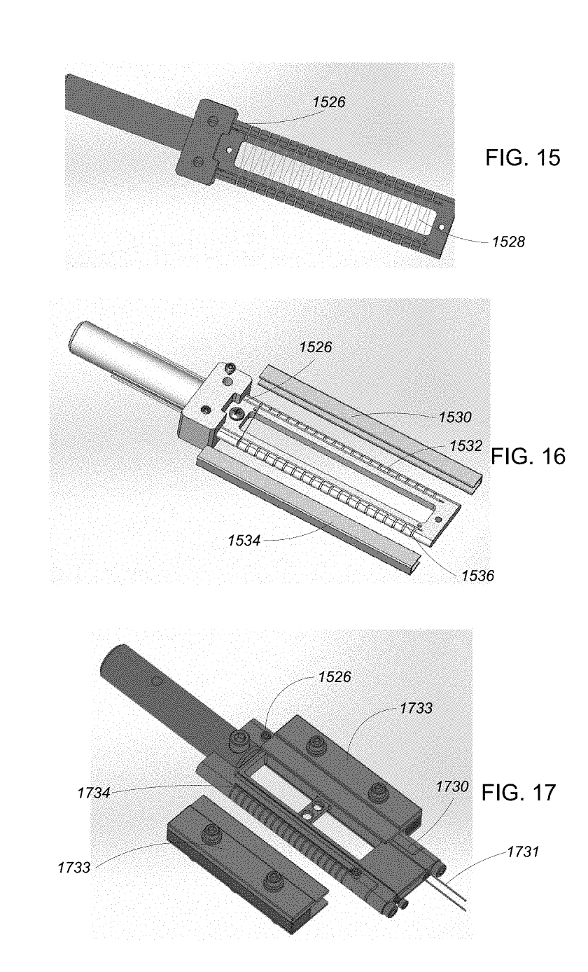

Referring to FIGS. 15-17, in some examples, miniature coaxial wires are fabricated using a specialized fixture.

Referring to FIG. 15, the fixture includes a spool 1526 onto which a length of insulated wire 1528 is wound. Referring to FIG. 16, once the length of insulated wire 1528 is wound onto the spool 1526, a first masking member 1530 is placed over a first edge 1532 of the spool 1526 such that portions of the insulated wire 1528 on the first edge 1532 of the spool 1526 are covered by the first masking member 1530. A second masking member 1534 is placed over a second edge 1536 of the spool 1526 such that portions of the insulated wire 1528 on the second edge 1536 of the spool 1526 are covered by the second masking member 1534. In some examples, with the first masking member 1530 and the second masking member 1534 attached to the spool 1526 of the fixture, the fixture undergoes a plating seed layer deposition. The seed layer deposition happens only on the portion of the wire 1528 between the first edge 1532 and second edge 1536 of the spool 1526. After seed layer deposition, the masking members 1530 and 1534 are removed. The seed layer is only deposited on unmasked portions of the wire 1528.

In one example, the seed material is a layer of Ti for adhesion to the dielectric and a layer of Au on top of the Ti. This is a seed for Au plating. In another example, the seed material is a layer of Ti for adhesion to the dielectric and a layer of Cu on top of the Ti. This is a seed for Cu plating. In another example, the seed could be a Cu/Mn alloy as a seed for Cu plating. In another example the seed could be Pt in preparation for Ni, Au or Cu plating. The seed layer can be deposited in a sputtering tool, evaporation tool, ALD (atomic layer deposition) tool, or CVD (chemical vapor deposition) tool. After the deposition process, masking members 1530 and 1534 are removed from the fixture.

In general, a distance between the first edge 1532 of the spool 1526 and the second edge 1536 of the spool 1526 determines a length of the miniature coaxial wires that are fabricated using the fixture.

Referring to FIG. 17, the fixture is configured to perform an electroplating procedure on portions of the insulated wire that are not masked (e.g. by the first and second masking members 1530, 1534), as is described in greater detail below.

For electroplating, a second set of masking members 1730, 1734 are attached to the fixture 1526. Additionally, the plating contact, a conductive wire 1731, is attached. Clamping members 1733 are placed on the second set of masking members 1730, 1734 and apply pressure on the conductive plating bath contact creating an electrical connection between the seed layer that was deposited in the previous step on 1528, to the electrical source that provides the electrical potential for plating the segments of the wire between edges 1532 and 1536. Once these new items are attached to the spool 1526, the fixture can be inserted into the plating bath for plating. Plated materials include, but are not limited to Cu, Au, Ni, Solder.

Once the electroplating procedure is complete, the masking member 1530, 1534 can be removed and the miniature coaxial wires are formed by cutting the wires in the area where no electroplating occurred (e.g., the masked areas of the wire).

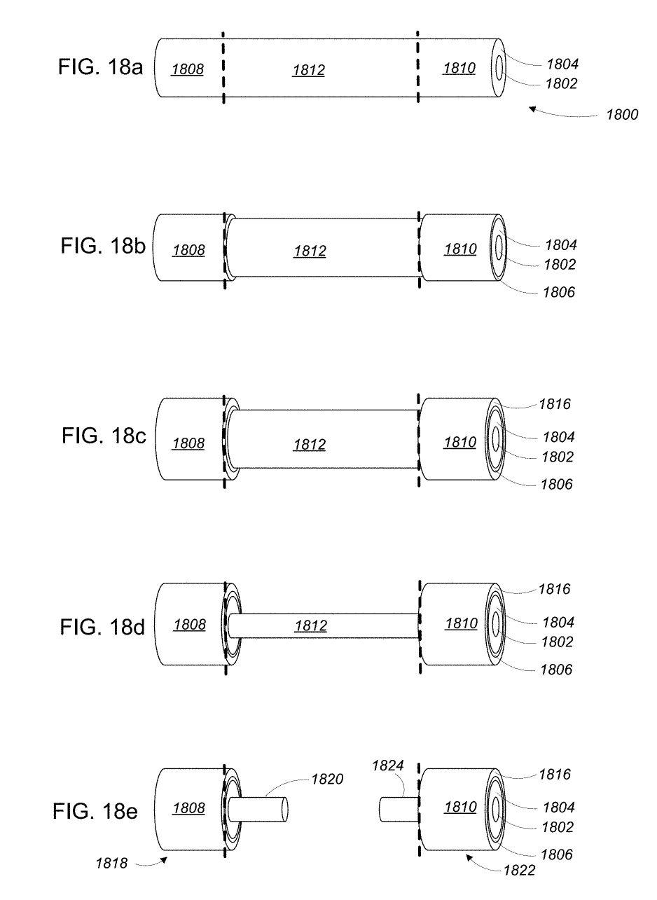

Referring to FIGS. 18a-18e, the fixture-based miniature coaxial wire fabrication procedure is explained in detail.

Referring to FIG. 18a, the fabrication method begins by receiving a length of insulated wire 1800. The length of insulated wire includes an electrically conductive inner core 1802 surrounded by an electrically insulating layer 1804. To aid in the explanation of the fabrication method, the insulated wire 1800 is described as having three segments, a first segment 1808, a second segment 1810, and a third segment 1812 disposed between the first segment 1808 and the second segment 1810. The length of insulating wire 1800 is wound on the spool 1526 of FIG. 15, with the third segment(s) 1812 of the length of insulated wire 1800 being disposed on the edges 1532, 1532 of the spool 1526. The third segment(s) 1812 of the length of insulated wire 1800 are covered by the masking members 1530, 1534 of the fixture.

Referring to FIG. 18b, an adhesion layer 1806 is deposited on the electrically insulating layer 1804 of the first segment 1808 of the electrically insulating layer 1804 and on the second segment 1810 of the electrically insulating layer 1804. The masking members 1530, 1534 of the fixture prevent deposition of the adhesion layer 1806 on the third segment 1812 of the electrically insulating layer 1804. In general, the adhesion layer serves to facilitate adhesion of an electroplated material to the insulated wire (as is described in detail below).

The masking members 1530 and 1534 are removed and replaced with the second set of masking members 1730, 1734 of FIG. 17. Additionally, the plating contact wire 1731 of FIG. 17 is inserted into the spool of the fixture 1526, making contact with the seed metal. The non-conductive clamps 1733 FIG. 17 ensure that the seed metal makes contact with the plating current source wire.

Referring to FIG. 18c, after deposition of the adhesion layer 1806, an electrically conductive shield layer 1816 is deposited on the first segment 1808 and the second segment 1810 (but not the third segment 1812, due to the presence of the masking members 1530, 1534).

Referring to FIG. 18d, after deposition of the electrically conductive shield layer 1816, the second set of masking members 1730, 1734 are removed and the electrically insulating layer 1804 of the insulated wire 1800 is removed from the third segment 1812, exposing the electrically conductive core 1802 in the third segment 1812. In some examples, the electrically insulating layer 1804 is removed using a laser cutting/etching process.

Referring to FIG. 18e, the electrically conductive core 1802 in the third segment 1812 is bisected (e.g., using a wire cutter or a blade), creating a first length of miniature coaxial wire 1818 with a first exposed section 1820 of electrically conductive core 1802 and a second length of miniature coaxial wire 1822 with a second exposed section 1824 of electrically conductive core 1802. In general, bisection of the third segment 1812 can occur either with the wire on the spool 1526 or with the wire off of the spool 1526.

In general, the procedure above can be used to generate a number of miniature coaxial wires, all with the same length, from a length of insulated wire. The length of the miniature coaxial wires generated by the fabrication procedure can be specified to meet the needs of a given application.

### 2.3.3 MEMS Based Fabrication

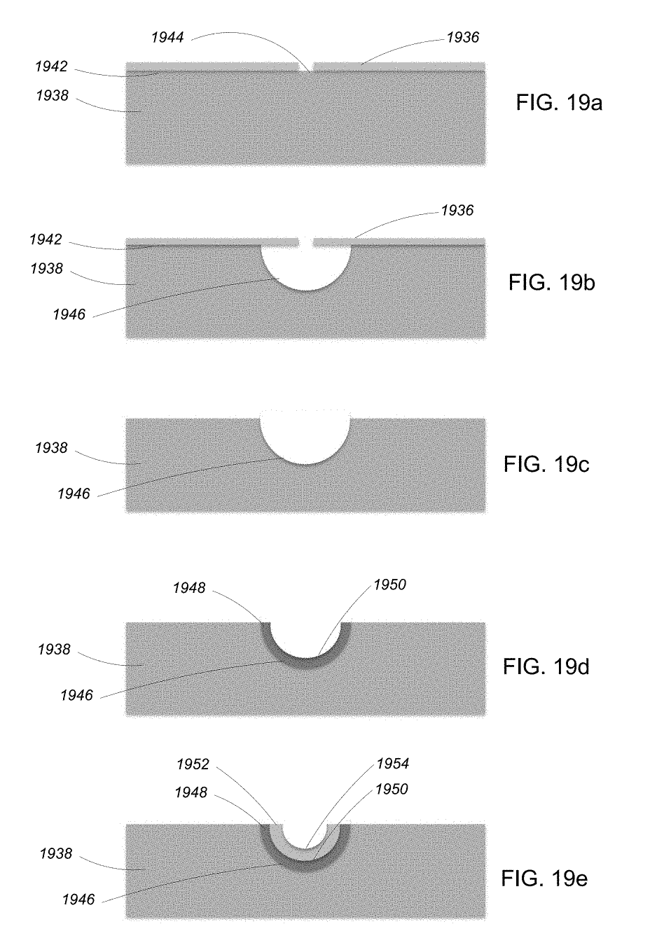

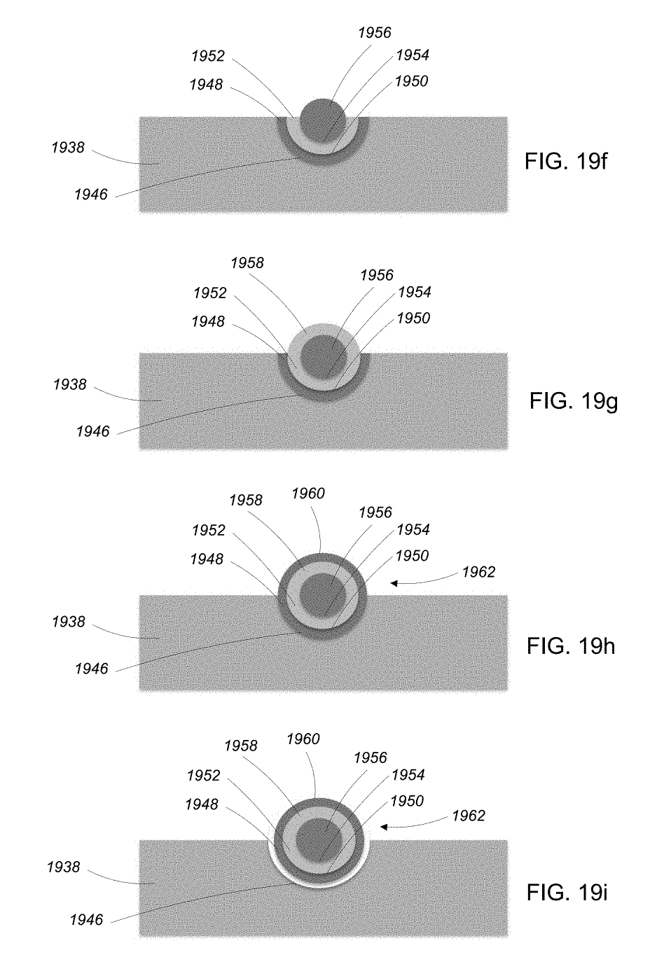

Referring to FIGS. 19a-19i, in some examples, miniature coaxial wires are fabricated using MEMS techniques.

Referring to FIG. 19a, in a first step, a masking layer 1936 (e.g., a polysilicon layer) is deposited on a substrate 1938 (e.g., a fused silica wafer) in a masking pattern 1940. In general, the masking pattern 1940 causes a first portion 1942 of the substrate 1938 to be covered by the masking layer 1936 and a second portion 1944 of the substrate 1939 to remain uncovered by the masking layer 1936. In the example of FIG. 19a, the masking pattern is simple (i.e., the second portion 1944 of the substrate that remains uncovered is a straight line extending into/out of the page). However, more complex masking patterns are likely to be used.

Referring to FIG. 19b, an etching procedure (e.g., a hydrofluoric acid etching procedure) is performed to remove material from the substrate 1938 in the area of the second portion 1944. In some examples, the material is removed such that a semicircular first cavity 1946 is formed in the substrate 1938.

Referring to FIG. 19c, after the etching procedure is performed, the masking layer 1936 is removed (e.g., using a polysilicon stripping procedure), exposing the substrate 1938.

Referring to FIG. 19d, a seed layer is deposited in the first cavity 1946 and a first part of a conductive shield layer 1948 (e.g., a copper layer) is deposited (e.g., electroplated or electroless plated) on the seed layer such that the first part of the conductive shield layer 1948 lines the first cavity 1946. A second cavity 1950 is formed by the first part of the conductive shield layer 1948.

Referring to FIG. 19e, a first part of an electrically insulating layer 1952 is deposited (e.g. by spraying photo-definable polyimide material) in the second cavity 1950 such that the first part of the electrically insulating layer 1952 lines the second cavity 1950. A third cavity 1954 is formed by the first part of the electrically insulating layer 1952.

Referring to FIG. 19f, a seed layer is deposited in the third cavity 1954 and an electrically conductive core 1956 (e.g., a copper core) is deposited on the seed layer in the third cavity 1954.

Referring to FIG. 19g, a second part of the electrically insulating layer 1958 is deposited (e.g., by spraying photo-definable polyimide material) on the electrically conductive core 1956 such that the first part of the electrically insulating layer 1952 and the second part of the electrically insulating layer 1958 encase the electrically conductive core 1956.

Referring to FIG. 19h, a seed layer is deposited on the second part of the electrically insulating layer 1958 and a second part of the conductive shield layer 1960 (e.g., a copper layer) is deposited (e.g. electroplated or electroless plated) on the seed layer such that the first part of the electrically conductive shield layer 1948 and the second part of the electrically conductive shield layer 1960 encase the electrically insulating layer. In FIG. 19h, the miniature coaxial wire 1962 is formed, but is still attached to the substrate 1938.

Referring to FIG. 19i, a glass etching procedure (e.g. a hydrofluoric acid etching procedure) is performed to release the miniature coaxial wire 1962 from the first cavity 1946.

### 2.4 Miscellaneous Miniature Coaxial Wire Features

In some examples, the electrically conductive materials and the electrically insulating materials are chosen to ensure that the two material types are compatible. For example, Ti is chosen as an adhesion layer because it sticks well to polymers, such as polyimide, polyurethane and polyester-imide. Additionally, aluminum doped silicon adheres better to Cu than does pure silica. A Cu/Mn alloy can be deposited using CVD onto a polymer or ceramic material and provides both good adhesion and a good electroplating foundation.

In some examples, at least some steps of certain miniature coaxial fabrication methods can be performed in a reel-to-reel system. For example, wires are configured to travel from a first reel, through various coating/electroplating stages, and onto a second reel.

In some examples the electrically conductive shields are formed from a solder-based material. In some examples, the electrically conductive shields and/or the electrically conductive inner cores are formed from low atomic weight materials (e.g., aluminum or beryllium) and the electrically insulating layer is formed from a low density polymer. In some examples, Kevlar insulation or threads can be used to strengthen the miniature coaxial wires.

In some examples, all three sections of the insulated wire are plated with a thermally removable shield layer (e.g., a solder based shield), and the portion of the thermally removable shield layer on the third segment of the insulated wire is thermally removed during the fabrication process.

In some examples, the electrically conductive inner core is formed from one or more of a copper material, a gold material, a silver material, a tin material, a nickel material, or an alloy of one or more of a copper material, a gold material, a silver material, a tin material, a nickel material.

In some examples, the electrically conductive shield layer is formed from one or more of a copper material, a gold material, a silver material, a tin material, a nickel material, or an alloy of one or more of a copper material, a gold material, a silver material, a tin material, a nickel material.

In some examples, the electrically conductive shield layer is deposited by drawing the insulated wire through a suspension of metallic particles in a polymeric material. The metallic particles may include one or more of metallic flakes, metallic nanoparticles, and metallic microparticles. The metallic particles may be formed from one or more of a copper material, a gold material, a silver material, a tin material, a nickel material, or an alloy of one or more of a copper material, a gold material, a silver material, a tin material, a nickel material.

In some examples, the electrically conductive shield layer is deposited by vapor depositing the shield layer.

In some examples, the adhesion layer includes an organic adhesion promoter.

### 3 Tooling

In some examples, specialized tools are used to fabricate, handle, route, and attach the miniature coaxial wires.

### 3.1 Wire Handling/Stripping

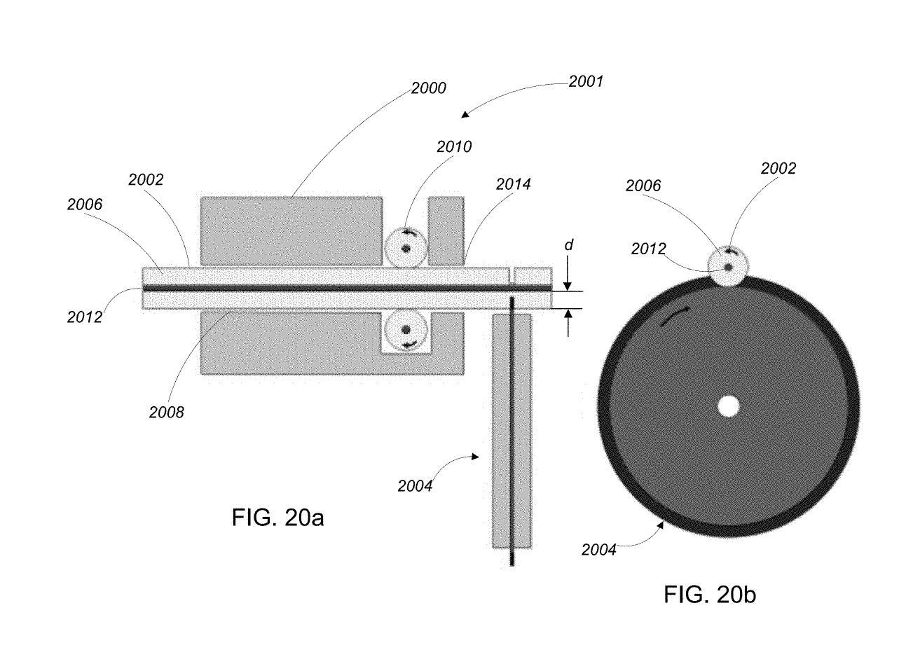

Referring to FIG. 20A and FIG. 20B, an apparatus 2001 for feeding and layer removal of coaxial wires includes a tubular feed mechanism 2000 for feeding and rotating a coaxial wire 2002 and a spinning cutting blade 2004 for cutting through one or more layers 2006 of the coaxial wire.

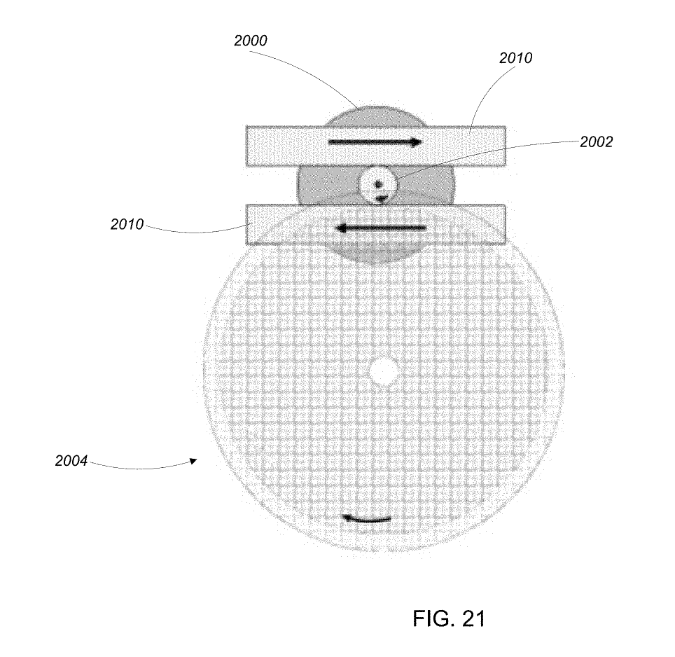

The tubular feed mechanism 2000 includes a tube 2008 and more rotating shafts 2010 disposed adjacent to the tube 2008 for engaging an outer surface of the coaxial wire 2002. The rotation of the shafts 2010 feeds (i.e., pushes or pulls) the coaxial wire 2002 through the tube 2008. In some examples, the shafts 2010 also move linearly along their own axes see (e.g., FIG. 21), causing rotation of the coaxial wire about its core 2012. In general, the shafts 2010 are capable of rotating the wire at least 360 degrees about its core 2012.

The spinning cutting blade 2004 is disposed adjacent to and just outside an opening 2014 of the tube 2008, and is configured to make an incision about the entire circumference of the coaxial wire 2002 to a predetermined depth, d as the wire 2002 rotates about its core 2012.

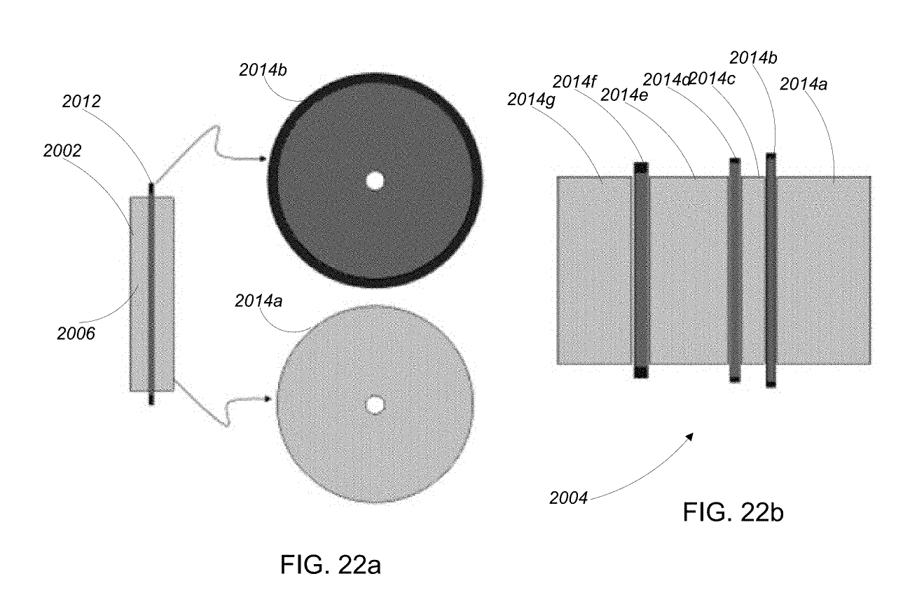

Referring to FIG. 22a and FIG. 22b, in some examples, to precisely cut insulation and shielding to a required depth, the spinning cutting blade 2004 is comprised of multiple stacked disks 2014a-2014g. One or more of the disks (e.g., 2014b, 2014d, 2014f) are cutting blades while others of the disks are stops (e.g., 2014a, 2014c, 2014e, 2014g). The disks are stacked so that the cutting disks sit between two stop disks. By setting a diameter of the cutting disks to be larger than the stop disks, the penetration (i.e., depth) of the cut is governed by the difference in radii between the particular cutting disk and stop disks. The disk diameters are machined to high precision to ensure that the cut depth of each cutting disk is precise.

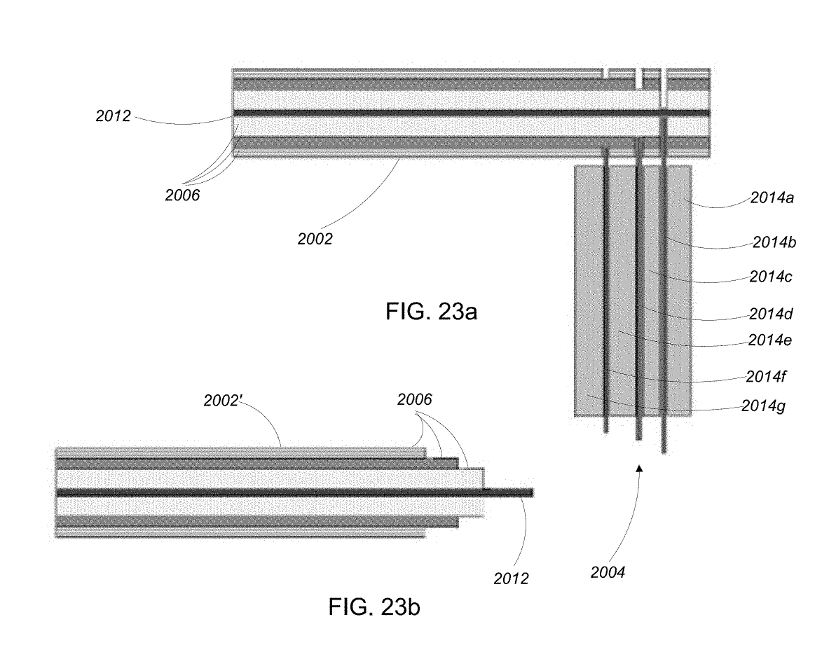

Referring to FIG. 23a and FIG. 23b, a coaxial wire 2002 is shown engaged with the spinning cutting blade 2004, which has cut through a number of layers 2006 of the coaxial wire 2002. The result of cutting and removal of the layers 2006 from the coaxial wire 2002 is shown as a stripped coaxial wire 2002′.

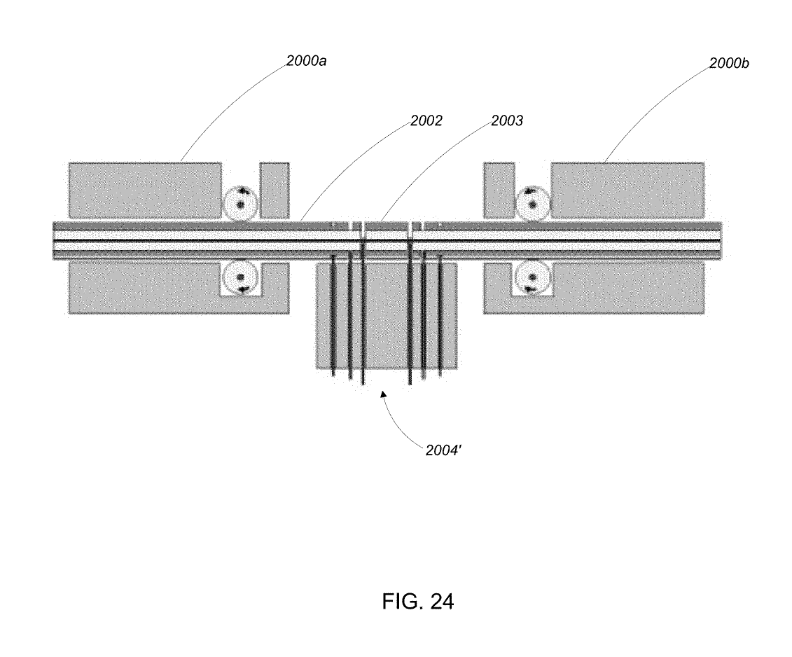

Multiple continuous feed configurations are possible using the above-described components. For example, referring to FIG. 24, two tubular feed mechanisms 2000a, 2000b can be used along with a compound spinning cutting blade 2004′ to remove layers of material from a midsection 2003 of a coaxial wire 2002 (rather than from an end section).

In an alternate embodiment, the spinning cutting blade 2004 can be fabricated as a cylindrical drum having uniform diameter with a cutting wire wrapped around the drum and adhered to the drum. In this configuration, the cutting wire diameter defines the cutting depth while the drum it is mounted to provides a cut-stop.

In some examples, the above-described apparatus is implemented as a modification to a conventional wirebonder. In some examples, the above-described tool is configured to operate on 1 mm diameter miniature coaxial wires.

### 3.2 Continuous Feed Attachment Tool

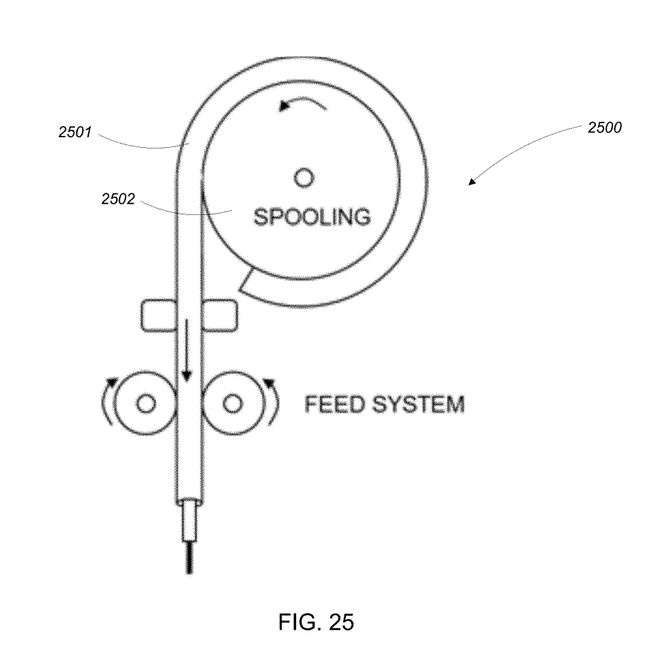

Referring to FIG. 25, in some examples an attachment tool 2500 continuously feeds miniature coaxial wire 2501 from a spool 2502 and attaches the miniature coaxial wire 2501 according to one or more of the attachment strategies described above.

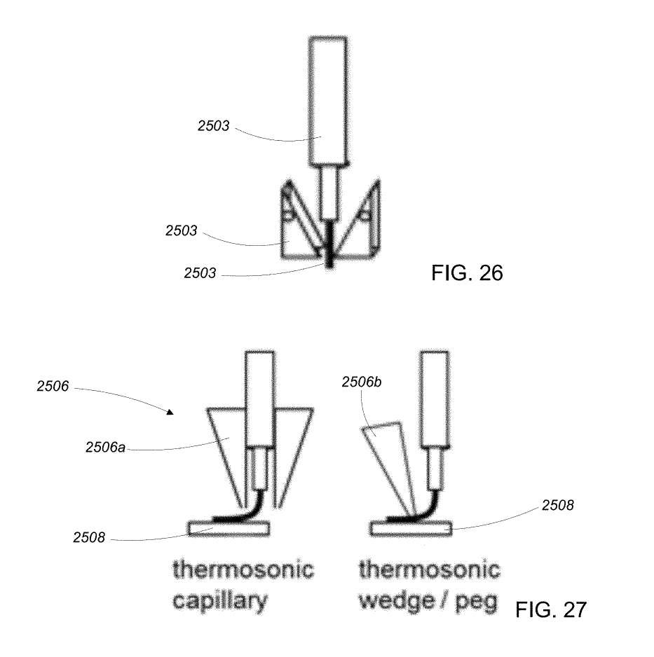

Referring to FIG. 26, in some examples, the attachment tool 2500 includes a wire stripper 2503 for stripping the miniature coaxial wire to expose the conductive inner core 2504. Referring to FIG. 27, in some examples, the attachment tool 2500 includes a welding apparatus 2506 (e.g., a thermosonic capillary welding apparatus 2506a or a thermosonic wedge/peg welding apparatus 2506b) for attaching the conductive inner core 2504 to a connection point 2508.

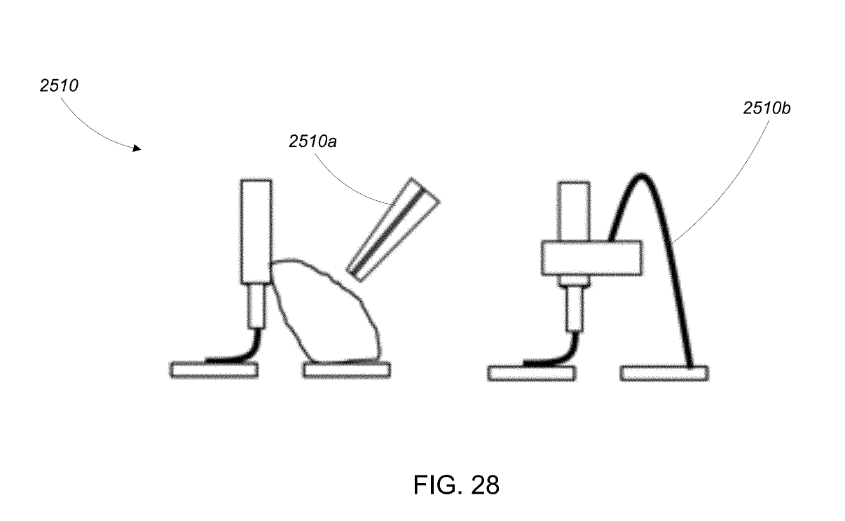

Referring to FIG. 28, in some examples, the attachment tool 2500 includes a shield attachment apparatus 2510 (e.g., a conductive material dispenser 2010a or a jumper wire attachment apparatus 2010b) for connecting the conductive shield of the miniature coaxial wire to ground (or another connection point).

In some examples, the attachment tool is configured to pick and place of pre-made miniature coaxial wires for wire attachment.

### 3.3 Wire Routing

In some examples, specialized wire routing algorithms are used to route the miniature coaxial wires. For example, the wire routing algorithms are configured to ensure that connection points are not obscured and inaccessible. The wire routing algorithms may plan non-straight line routes for the miniature coaxial wires to follow. In some examples, the wire routing algorithms may wrap the miniature coaxial wires around posts in the circuit to facilitate certain non-straight line routes.

In some examples, the routing algorithms may generate three-dimensional wiring maps.

It is to be understood that the foregoing description is intended to illustrate and not to limit the scope of the invention, which is defined by the scope of the appended claims. Other embodiments are within the scope of the following claims.

1. A method for attaching a prefabricated miniature coaxial wire to a first electrical connection point, the prefabricated miniature coaxial wire having an electrically conductive core disposed within an electrical insulation layer disposed within an electrically conductive shield layer, the method comprising:
attaching an exposed portion of the electrically conductive core at a distal end of the prefabricated miniature coaxial wire to the first electrical connection point, thereby establishing electrical conductivity between the electrically conductive core and the first electrical connection point;
depositing a layer of electrically insulating material onto the exposed portion of the electrically conductive core such that the exposed portion of the electrically conductive core and the first electrical connection point is encased in the layer of electrically insulating material; and
connecting the electrically conductive shield layer to a second electrical connection point using a connector formed from an electrically conductive material.

2. The method of claim 1 wherein connecting the electrically conductive shield layer to the second electrical connection point using the connector includes forming the connector including depositing a layer of the electrically conductive material onto at least a portion of the electrically conductive shield layer and onto the second electrical connection point, the connector establishing electrical conductivity between the electrically conductive shield layer and the second electrical connection point.

3. The method of claim 2 wherein depositing the layer of the electrically conductive material onto the at least a portion of the electrically conductive shield layer and onto the second electrical connection point includes one of flowing the electrically conductive material onto the at least a portion of the electrically conductive shield layer and onto the second electrical connection point, spray coating the electrically conductive material onto the at least a portion of the electrically conductive shield layer and onto the second electrical connection point, vapor depositing the electrically conductive material onto the at least a portion of the electrically conductive shield layer and onto the second electrical connection point, sputtering the electrically conductive material onto the at least a portion of the electrically conductive shield layer and onto the second electrical connection point, and plating the electrically conductive material onto the at least a portion of the electrically conductive shield layer and onto the second electrical connection point.

4. The method of claim 2 wherein the layer of electrically insulating material encases the first electrical connection point and the layer of electrically conductive material encases the layer of electrically insulating material.

5. The method of claim 2 wherein the layer of electrically conductive material partially encases the layer of electrically insulating material.

6. The method of claim 1 wherein an exposed portion of the electrical insulation layer at the distal end of the prefabricated miniature coaxial wire is encased in the layer of electrically of insulating material.

7. The method of claim 1 wherein depositing the layer of electrically insulating material onto the exposed portion of the electrically conductive core includes depositing a bead of the electrically insulating material onto the exposed portion of the electrically conductive core.

8. The method of claim 1 wherein depositing the layer of electrically insulating material onto the exposed portion of the electrically conductive core includes flowing the electrically insulating material onto the exposed portion of the electrically conductive core.

9. The method of claim 1 wherein depositing the layer of electrically insulating material onto the exposed portion of the electrically conductive core includes vapor depositing the electrically insulating material onto the exposed portion of the electrically conductive core.

10. (canceled)

11. The method of claim 1 wherein depositing the layer of electrically insulating material onto the exposed portion of the electrically conductive core includes aerosol jetting the electrically insulating material onto the exposed portion of the electrically conductive core.

12. The method of claim 1 wherein connecting the electrically conductive shield layer to the second electrical connection point using the connector includes printing the connector as a strip of the electrically conductive material.

13. The method of claim 1 wherein the connector includes a wire and connecting the electrically conductive shield layer to the second electrical connection point using the connector includes attaching a first end of the wire to the first electrical connection point and attaching a second end of the wire to the second electrical connection point.

14. The method of claim 1 wherein attaching the exposed portion of the electrically conductive core to the first electrical connection point includes attaching a conductive pad to the first electrical connection point and then attaching the electrically conductive core to the conductive pad.

15. The method of claim 1 wherein the first electrical connection point is a connector pad on a bare die.

16. The method of claim 1 wherein the electrical first connection point is a connector pad on a packaged part.

17. The method of claim 1 wherein the first electrical connection point is a ball on a ball grid array.

18.-19. (canceled)

20. The method of claim 1 wherein the first electrical connection point includes an electrically conductive via disposed in a circuit board.

21. The method of claim 1 wherein the first electrical connection point includes a conductive plane or a conductive trace disposed on a circuit board.

22. The method of claim 1 wherein attaching the exposed portion of the electrically conductive core to the first electrical connection point includes soldering the electrically conductive core to the first electrical connection point.

23. The method of claim 1 wherein attaching the exposed portion of the electrically conductive core to the first electrical connection point includes welding the electrically conductive core to the first electrical connection point.

24.-25. (canceled)

26. The method of claim 1 wherein the second electrical connection point includes a ground connection point.

27. The method of claim 1 further comprising forming the connector including welding the electrically conductive shield layer to a second electrical connection point.

28.-84. (canceled)
